(19) United States
(12) Patent Application Publication
(10) Pub. No.: US 2025/0359310 A1
(43) Pub. Date: Nov. 20, 2025

(54) GATE EXTENSION FOR BACKSIDE CLOCK WIRING

(71) Applicant: International Business Machines Corporation, Armonk, NY (US)

(72) Inventors: Tsung-Sheng Kang, Ballston Lake, NY (US); Tao Li, Slingerlands, NY (US); Ruilong Xie, Niskayuna, NY (US); Ravikumar Ramachandran, Pleasantville, NY (US)

(21) Appl. No.: 18/665,638

(22) Filed: May 16, 2024

(51) Int. Cl. H01L 27/092; H01L 21/8238; H01L 23/528; H01L 29/417

(52) U.S. Cl. CPC H10D 84/85; H01L 23/528; H10D 64/254; H10D 84/0186; H10D 84/038

(57) ABSTRACT

Embodiments of the present disclosure include a semiconductor structure having a transistor including epitaxial regions and a gate structure at a frontside, a gate extension being connected at the frontside to the gate structure and extending to a backside, the frontside being opposite the backside. A backside gate contact is connected at the backside to the gate extension. A source/drain via is coupled to one of the epitaxial regions, the source/drain via extending through the gate structure from the frontside to the backside, the gate extension extending further in the backside than the source/drain via.

### BACKGROUND

The present invention generally relates to fabrication methods and resulting structures for integrated circuits (ICs), and more specifically, to fabrication methods and resulting structures for gate extension for backside clock wiring with substrate grounding.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to a semiconductor structure having a gate extension for backside clock wiring with substrate grounding. A non-limiting semiconductor structure includes a transistor having epitaxial regions and a gate structure at a frontside, a gate extension being connected at the frontside to the gate structure and extending to a backside, the frontside being opposite the backside. The semiconductor structure includes a backside gate contact connected at the backside to the gate extension. The semiconductor structure includes a source/drain via coupled to one of the epitaxial regions, the source/drain via extending through the gate structure from the frontside to the backside, the gate extension extending further in the backside than the source/drain via.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, and 1C respectively depict a top view and cross-sectional views of a portion of an integrated circuit (IC) according to one or more embodiments of the invention;

FIGS. 2A, 2B, and 2C respectively depict a top view and cross-sectional views of a portion of an IC under-fabrication after fabrication operations according to one or more embodiments of the invention;

FIGS. 3A, 3B, and 3C respectively depict a top view and cross-sectional views of a portion of an IC under-fabrication after fabrication operations according to one or more embodiments of the invention;

FIGS. 4A, 4B, and 4C respectively depict a top view and cross-sectional views of a portion of an IC under-fabrication after fabrication operations according to one or more embodiments of the invention;

FIGS. 5A, 5B, and 5C respectively depict a top view and cross-sectional views of a portion of an IC under-fabrication after fabrication operations according to one or more embodiments of the invention;

FIGS. 6A, 6B, and 6C respectively depict a top view and cross-sectional views of a portion of an IC under-fabrication after fabrication operations according to one or more embodiments of the invention;

FIGS. 7A, 7B, and 7C respectively depict a top view and cross-sectional views of a portion of an IC under-fabrication after fabrication operations according to one or more embodiments of the invention;

FIGS. 8A, 8B, and 8C respectively depict a top view and cross-sectional views of a portion of an IC under-fabrication after fabrication operations according to one or more embodiments of the invention;

FIGS. 9A, 9B, and 9C respectively depict a top view and cross-sectional views of a portion of an IC under-fabrication after fabrication operations according to one or more embodiments of the invention;

FIGS. 10A, 10B, and 10C respectively depict a top view and cross-sectional views of a portion of an IC under-fabrication after fabrication operations according to one or more embodiments of the invention;

FIGS. 11A and 11B depict cross-sectional views of a portion of an IC under-fabrication after fabrication operations according to one or more embodiments of the invention;

FIGS. 12A, 12B, and 12C respectively depict a top view and cross-sectional views of a portion of an IC under-fabrication after fabrication operations according to one or more embodiments of the invention;

FIGS. 13A, 13B, and 13C respectively depict a top view and cross-sectional views of a portion of an IC under-fabrication after fabrication operations according to one or more embodiments of the invention;

FIGS. 14A, 14B, and 14C respectively depict a top view and cross-sectional views of a portion of an IC under-fabrication after fabrication operations according to one or more embodiments of the invention;

FIGS. 15A, 15B, and 15C respectively depict a top view and cross-sectional views of a portion of an IC under-fabrication after fabrication operations according to one or more embodiments of the invention;

FIGS. 16A, 16B, and 16C respectively depict a top view and cross-sectional views of a portion of an IC under-fabrication after fabrication operations according to one or more embodiments of the invention;

FIGS. 17A, 17B, and 17C respectively depict a top view and cross-sectional views of a portion of an IC under-fabrication after fabrication operations according to one or more embodiments of the invention;

FIGS. 18A, 18B, and 18C respectively depict a top view and cross-sectional views of a portion of an IC under-fabrication after fabrication operations according to one or more embodiments of the invention;

FIGS. 19A, 19B, and 19C respectively depict a top view and cross-sectional views of a portion of an IC under-fabrication after fabrication operations according to one or more embodiments of the invention;

FIGS. 20A, 20B, and 20C respectively depict a top view and cross-sectional views of a portion of an IC under-fabrication after fabrication operations according to one or more embodiments of the invention;

FIGS. 21A, 21B, and 21C respectively depict a top view and cross-sectional views of a portion of an IC under-fabrication after fabrication operations according to one or more embodiments of the invention; and

FIGS. 22A, 22B, and 22C respectively depict a top view and cross-sectional views of a portion of an IC under-fabrication after fabrication operations according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

One or more embodiments of the invention include methods and structure arranged to provide a gate extension with backside clock wiring for front via backside power rail (FVBP) with substrate grounding. According to one or more embodiments, the present disclosure uses a front via backside power rail approach without extensive substrate recess on the backside, where the substrate is not down to about 30 nanometers (nm) under the transistor in typical situations. Rather, the substrate is grounded at the front-end-of-line (FEOL), and the severe substrate recess is avoided in one or more embodiments. Further, a connection to a backside clock signal wire is utilized to accommodate this approach, according to one or more embodiments.

The typical pathfinding scheme is to recess the silicon substrate and only leave about 30 nm of silicon under the transistor, and this substrate is not controlled by the gate but is floating. In the present disclosure, one or more embodiments leave the substrate but ground the substrate at a far distance away from the transistor using a (frontside source/drain) contact. Examples of a far distance away from the transistor for grounding the substrate with a contact may include 300 nanometers (nm) or more.

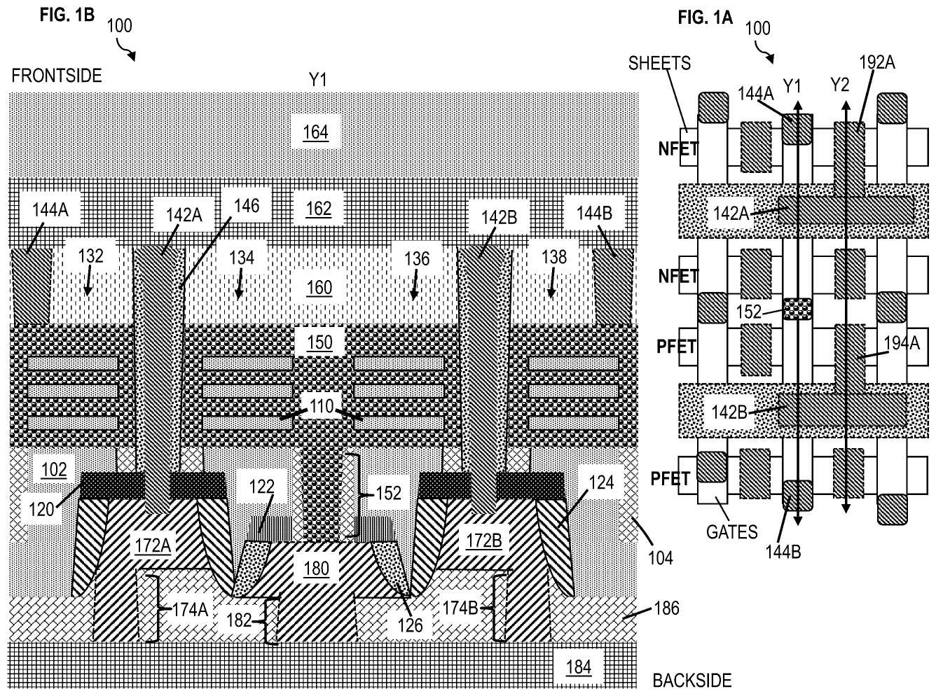

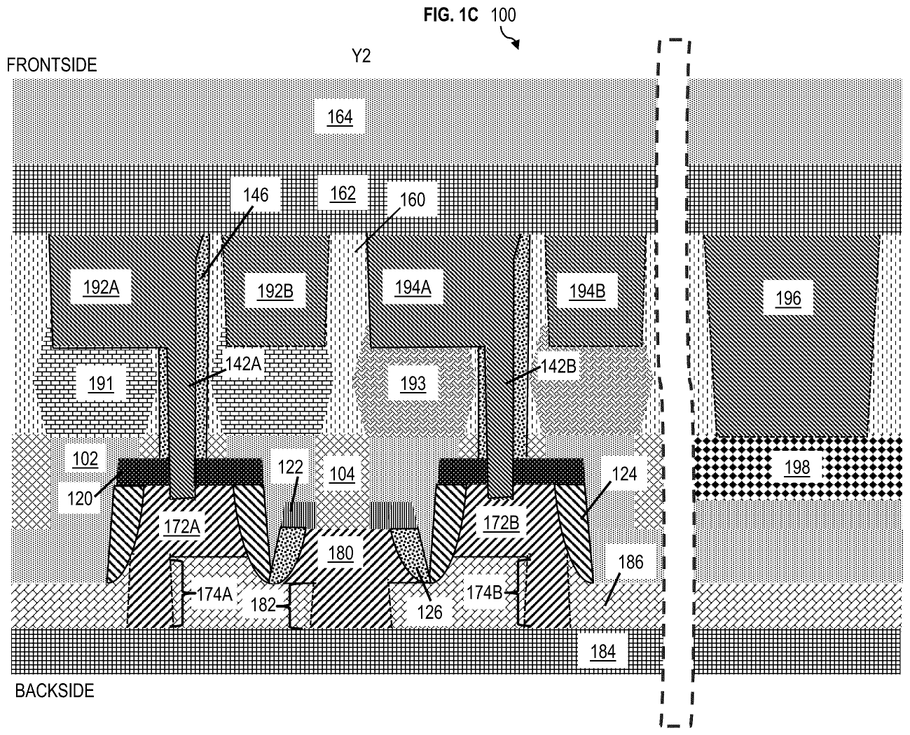

Turning now to a more detailed description of aspects of the present invention, FIG. 1A depicts a top view of a simplified illustration of a portion of an integrated circuit (IC) 100, FIG. 1B depicts a cross-sectional view taken along Y1 of the IC 100, and FIG. 1C depicts a cross-sectional view taken along Y2 of the IC. For ease of understanding, some layers may be omitted from the various top views so as not to obscure the figure and to view layers underneath. As such, the top view is intended to provide a simplified illustration and a general orientation of the IC, but the top view is not intended to represent every detail of the device. Standard semiconductor fabrication techniques can be utilized to fabricate IC 100 as understood by one of ordinary skill in the art. Any suitable lithography processes including deposition techniques and etching techniques can be utilized herein.

FIGS. 1A, 1B, and 1C depict the IC 100 with transistors 132, 134, 136, and 138 formed on a substrate 102. Shallow trench isolation (STI) regions 104 are formed in the substrate 102. The transistors 132 and 134 can be NFETs, and the transistors 136 and 138 can be PFETs. The transistors 132, 134, 136, and 138 include semiconductor layers 110 that act as channel regions, gate structure 150, and source/drain regions. The transistors 132 and 134 include epitaxial regions 191 as source/drain regions formed in frontside fill material 160. The transistors 136 and 138 include epitaxial regions 193 as source/drain regions formed in the frontside fill material 160.

Frontside source/drain contacts 192A and 192B are connected to the epitaxial regions 191, and frontside source/drain contacts 194A and 194B are connected to the epitaxial regions 193. A source/drain via 142A is connected to the frontside source/drain contact 192A on the frontside and connected to a backside source/drain contact 172A on the backside. Similarly, a source/drain via 142B is connected to the frontside source/drain contact 194A on the frontside and connected to a backside source/drain contact 172B on the backside. The source/drain vias 142A and 142B are surrounded by spacer material 146.

The source/drain vias 142A and 142B in the frontside fill material 160 respectively connect to a frontside interconnect 162. The gate structure 150 is respectively connected to the frontside interconnect 162 by frontside gate contacts 144A and 144B in the frontside fill material 160. The frontside interconnect 162 can be connected to a carrier wafer 164.

The backside source/drain contacts 172A and 172B are respectively connected to backside vias 174A and 174B in backside fill material 186. Spacer material 124 surrounds the backside source/drain contacts 172A and 172B. The backside source/drain contacts 172A and 172B respectively connect to interconnections of a backside interconnect 184. Backside fill material 120 intervenes between the backside source/drain contacts 172A and 172B and the spacer material 146.

The gate structure 150 is connected to and/or includes a gate extension 152. The gate extension 152 extends through an STI region 104 from the gate structure 150 on the frontside to a backside gate contact 180 on the backside. The backside gate contact 180 is surrounded by spacer material 126 and contacts backside via 182 in the backside fill material 186. Spacer material 122 is formed around a portion of the STI region 104 through which the gate extension 152 extends. The backside via 182 connects to an interconnection of the backside interconnect 184.

Further, a highly doped region 198 is connected to and/or formed in a portion of the substrate 102. The highly doped region 198 is conductive and is used for grounding the substrate 102. For example, a (large) grounding contact 196 connects the highly doped region 198 to an interconnect of the frontside interconnect 162, so as to ground the substrate 102. The highly doped region 198 and the grounding contact 196 are positioned at a location/distance far away from the transistors 132, 134, 136, and 138. A location/distance far away from any one or more of the transistors can include, for example, 300 nm or more in one or more embodiments.

The fabrication process is discussed below. It is noted that the cross-sections taken along Y1 and Y2 may illustrate abbreviated versions and extended versions. It should be appreciated that analogous fabrication operations are performed even if an abbreviated version is depicted for the sake of brevity.

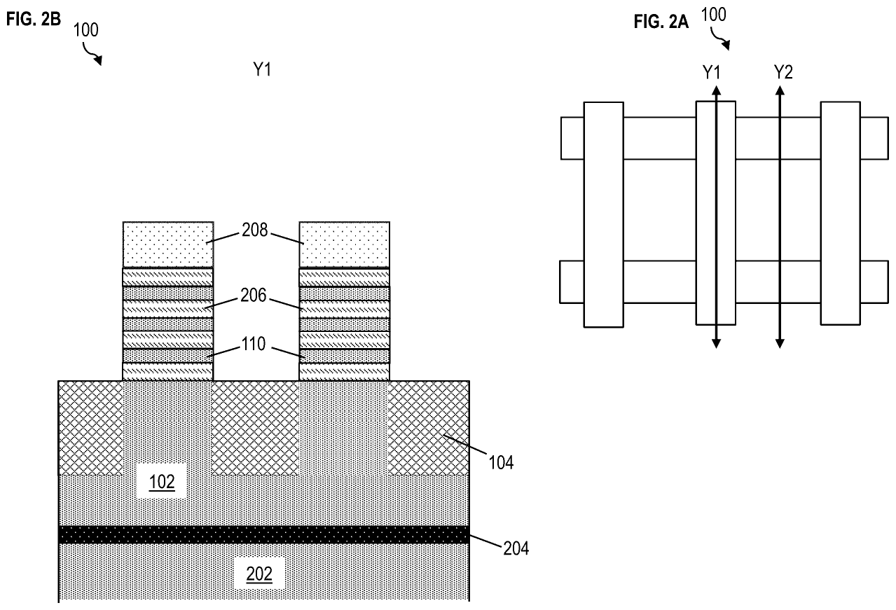

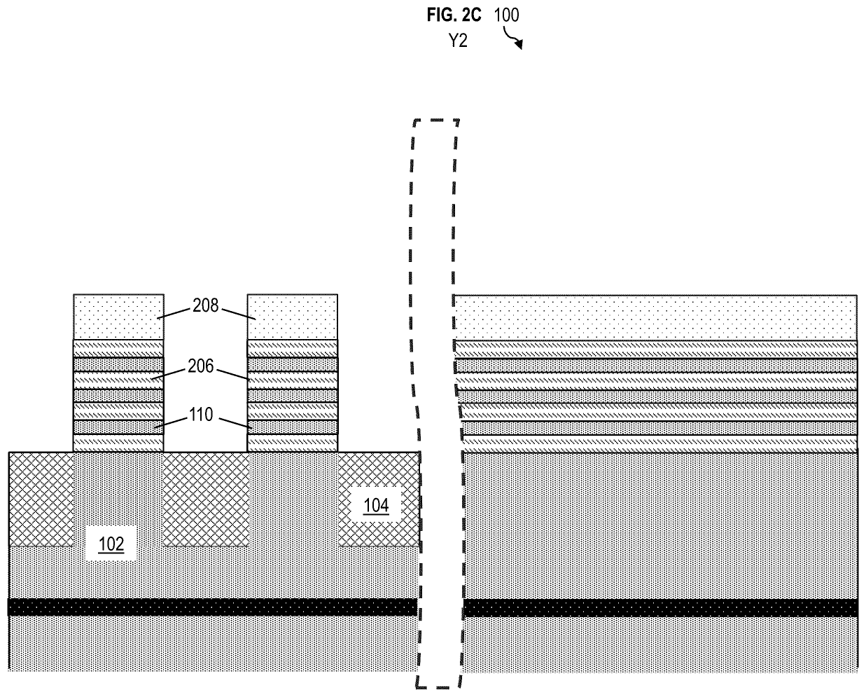

FIGS. 2A, 2B, and 2C depict the IC 100 having a wafer where several fabrication processes have been performed. A nanosheet stack is formed on a substrate 102. The wafer or substrate 102 may be formed of (pure) silicon. Other suitable materials can be utilized for the substrate 102.

Nanosheet stacks of semiconductor layers 110 are formed with sacrificial layers 206 formed in between, and a sacrificial layer 204 is formed underneath the substrate 102. The sacrificial layer 204 is between the substrate 102 and a lower substrate 202. The lower substrate 202 may be formed of silicon and may be considered a sub-substrate. The sacrificial layer 204 may server as an etch stop layer.

The semiconductor layers 110 may include substantially pure silicon. The semiconductor layers 110 will become the channel regions for the nanosheet FET devices. The semiconductor layers 110 are nanosheets. Nanosheets can have a thickness of, for example, about 5 nanometers. The thickness of a nanosheet can range from about 5-10 nm, and other ranges are possible. The sacrificial layers 206 and 204 are formed of silicon germanium (SiGe).

Fin patterning is performed to pattern the nanosheets into fins or fin modules. A fin hard mask layer 208 is formed and patterned using lithography. Example materials of the fin hard mask layer 208 can include nitride materials such as silicon nitride. The (patterned) fin hard mask layer 208 is utilized to transfer the pattern into the nanosheet stack and partially into the substrate 102, resulting in fins and STI trenches. STI fill material is deposited to fill the STI trenches, thereby forming STI regions 104. The STI fill material may be an oxide material such as silicon dioxide (SiO₂). The STI fill material can be a low-k dielectric material or ultra-low-dielectric material. In FIG. 2C and other figures, it is noted that the dashed lines represent portions of the IC 100 at a distance far away from the device.

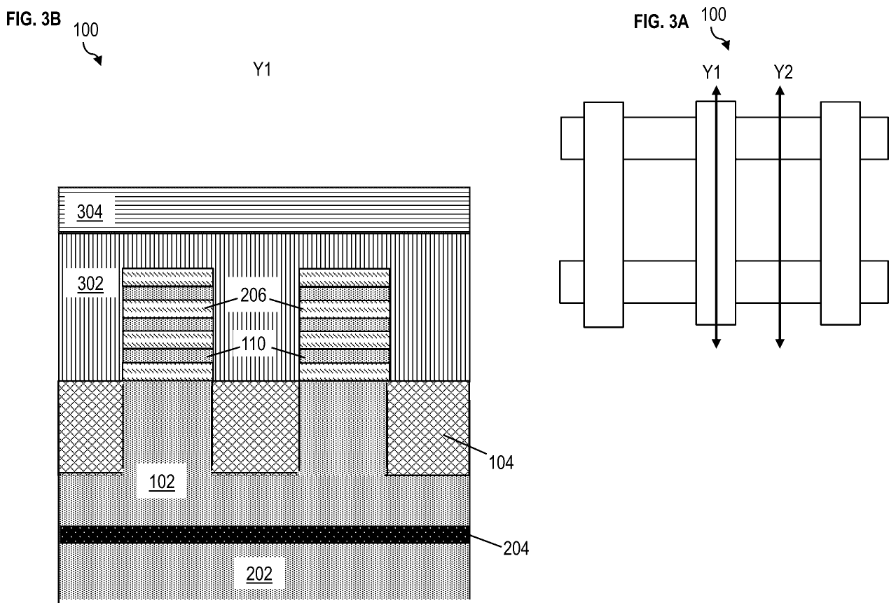

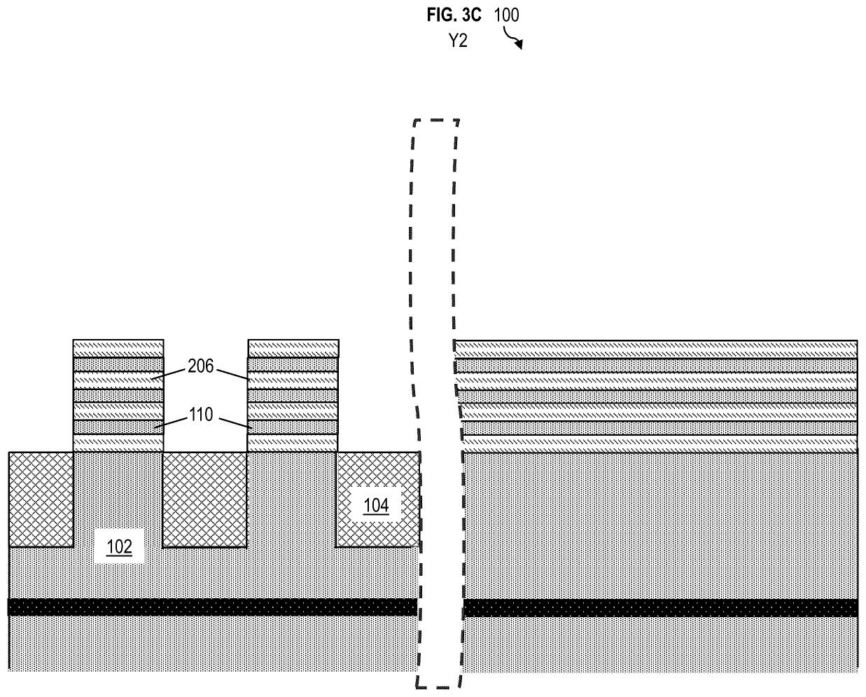

FIGS. 3A, 3B, and 3C depict the IC 100 after formation of the gate module. The fin hard mask layer 208 is removed. Dummy gate material 302 is formed and patterned using a gate hard mask layer 304. The gate hard mask layer 304 has been patterned to protect the desired regions in preparation for the replacement metal gate process. Example materials of the dummy gate material 302 can include amorphous silicon, polycrystalline silicon, etc. Example materials of the gate hard mask layer 304 can include nitride materials such as silicon nitride.

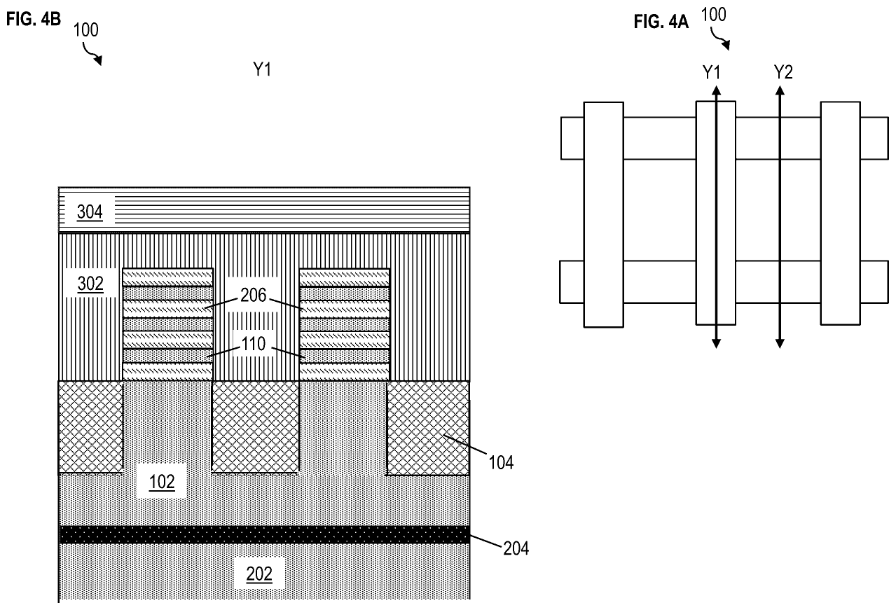

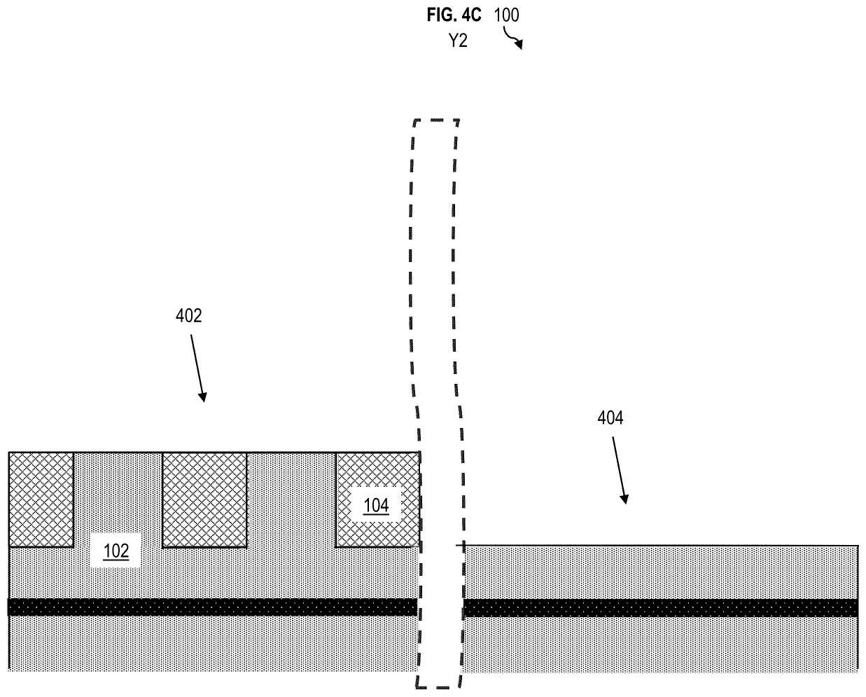

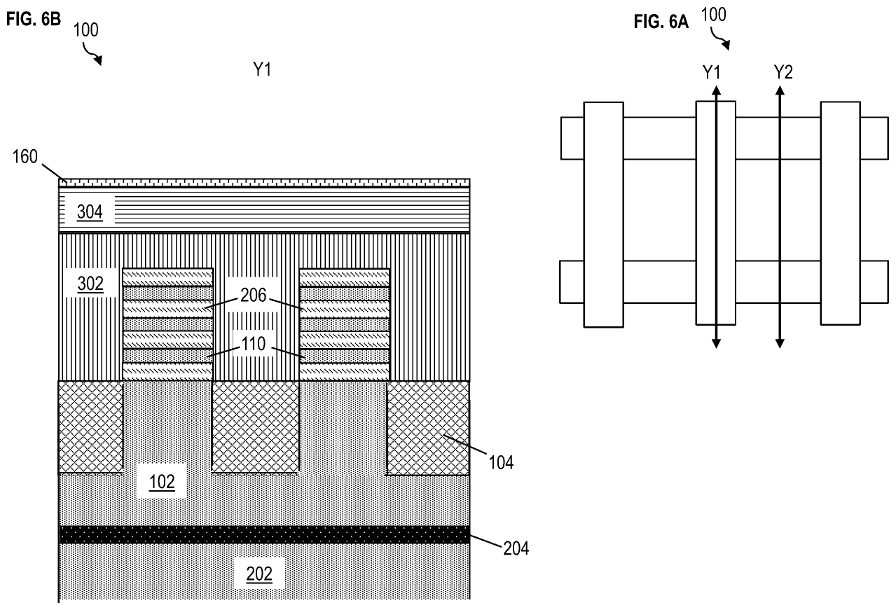

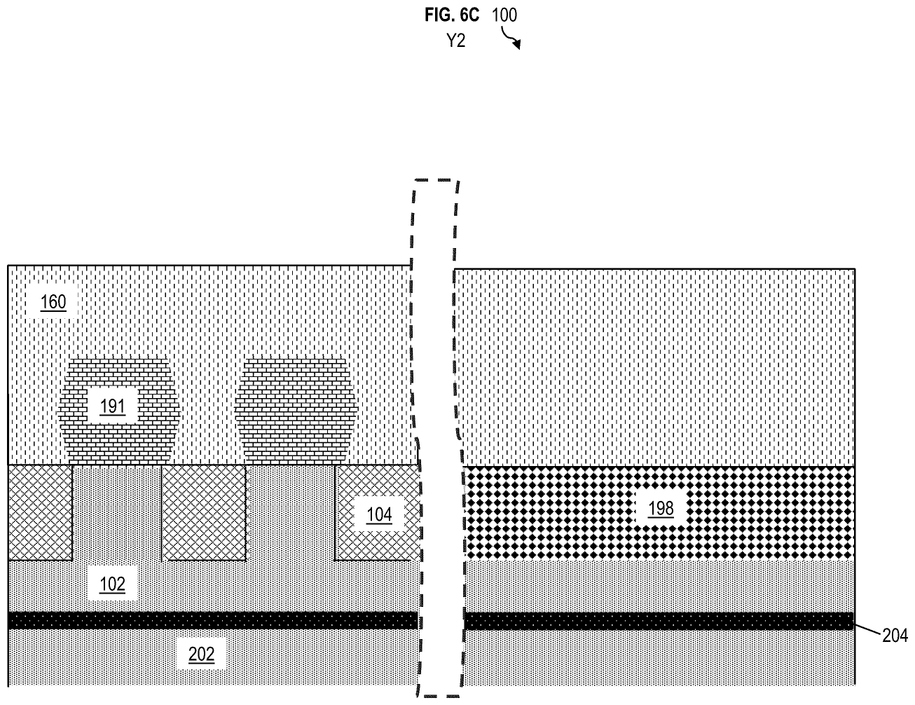

FIGS. 4A, 4B, and 4C depict the IC 100 after fin recess to form a cavity in preparation for source/drain epitaxial material. While the fin stack and dummy gate material 302 are protected by the gate hard mask layer 304, etching is performed to form cavity 402 in preparation to form epitaxial regions 191 and 193. Additionally, one or more embodiments perform further etching to form cavity 404 as an example option, which is in preparation to form the highly doped region 198. According to this example option, a new epitaxial layer is grown in the cavity 404 and is highly doped so as to be conductive for grounding the substrate 102 in one or more embodiments. The deposition of the highly doped epitaxial layer results in the highly doped region 198 depicted in FIG. 6C. In one or more embodiments, silicon germanium can be epitaxially grown and doped to become the highly doped region 198.

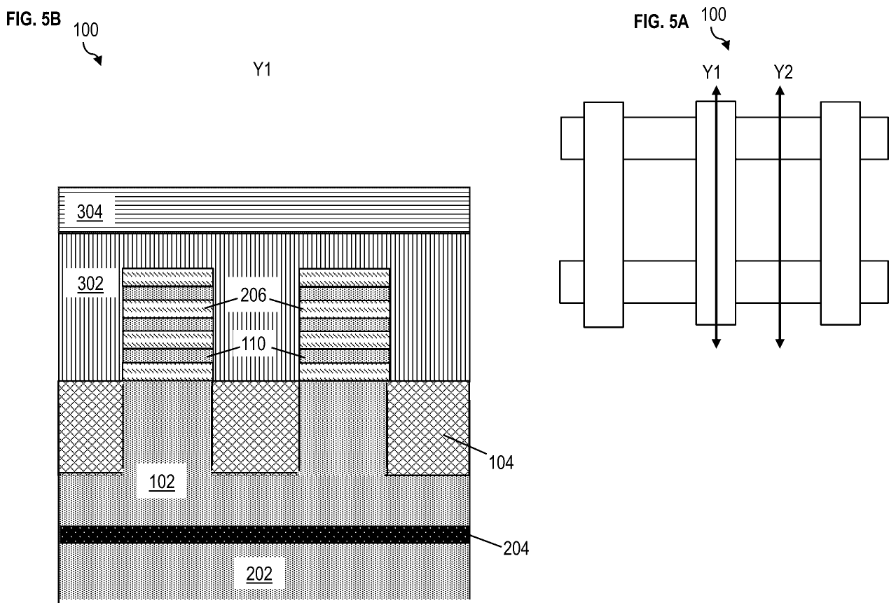

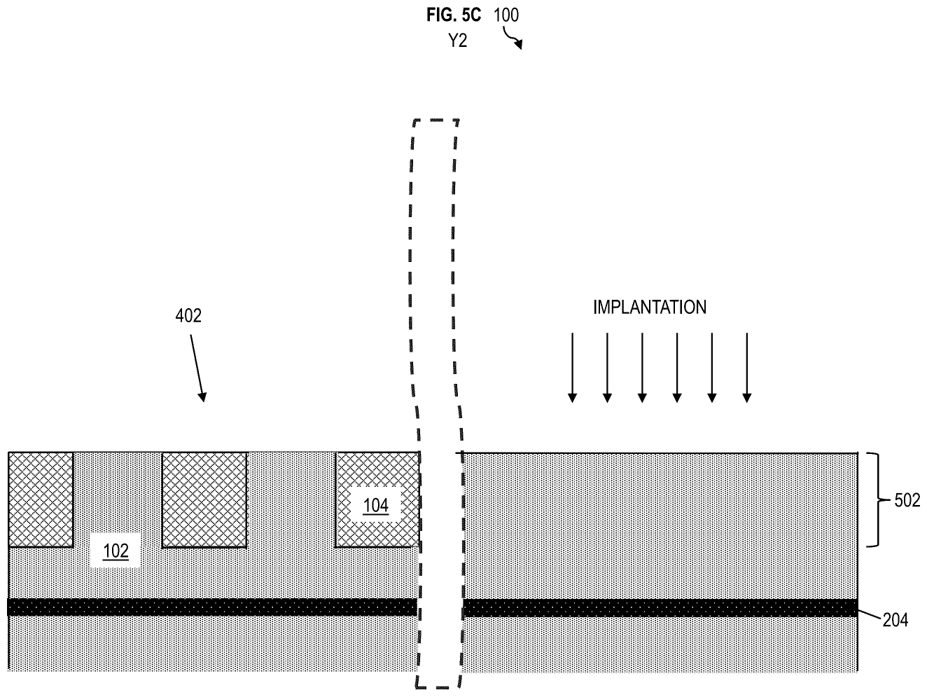

FIGS. 5A, 5B, and 5C depict the IC 100 after fin recess to form a cavity in preparation for source/drain epitaxial material. While the fin stack and dummy gate material 302 are protected by the gate hard mask layer 304, etching is performed to form cavity 402 in preparation to form epitaxial regions 191 and 193. According to one or more embodiments, the substrate 102 in region 502 is highly doped to become conductive, and this is another example of forming the highly doped region 198. Ion implantation of dopants may be utilized to form the highly doped region 198 as depicted in FIG. 6C.

FIGS. 6A, 6B, and 6C depict the IC 100 after source/drain formation and intralayer dielectric formation. The highly doped region 198 is formed by epitaxial growth with dopants as discussed in FIGS. 4A, 4B, and 4C or by ion implantation of dopants as discussed in FIGS. 5A, 5B, and 5C. The highly doped region 198 behaves as an electrode for grounding the substrate 102. Source/drain regions are formed by epitaxial growth. Although FIG. 6C is an abbreviated view that illustrates the epitaxial regions 191, it should be appreciated that epitaxial regions 193 are analogously formed. The epitaxial regions 191 and 193 can be respectively doped with n-type dopants and p-type dopants. A gate hard mask layer 304 is formed and patterned. Intralayer dielectric (ILD) material is deposited as frontside fill material 160.

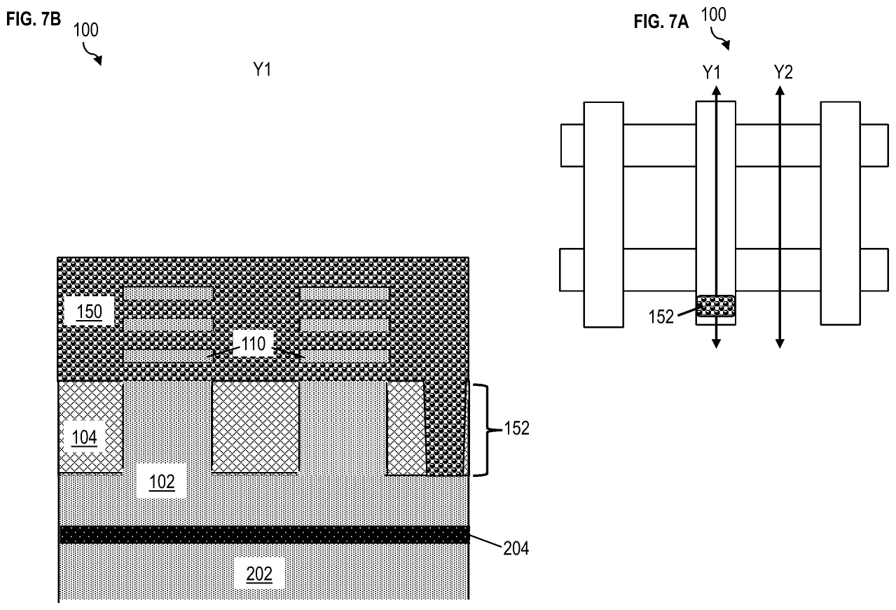

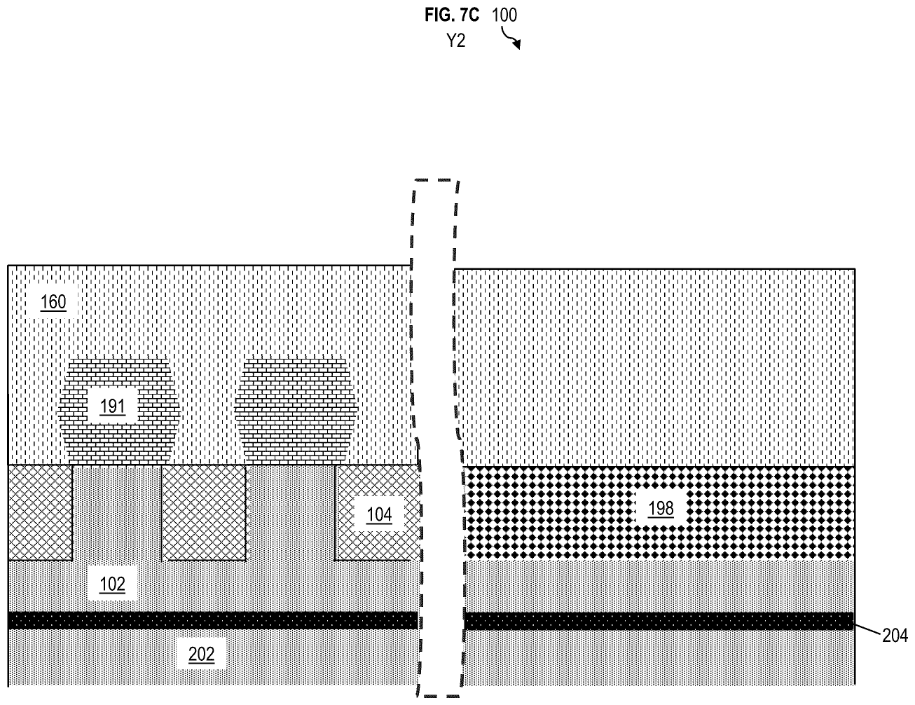

FIGS. 7A, 7B, and 7C depict the IC 100 after replacement metal gate (RMG) formation. The gate hard mask layer 304 is removed. Although not shown, it is understood that gate spacers are formed, the dummy gate material 302 is removed, inner spacers are formed between the semiconductor layers 110, and the nanosheets are released by etching the sacrificial layers 206.

The gate structure 150 is formed with the gate extension 152. For example, using lithography, a cavity is formed in the STI region 104, and the cavity is filled with material of the gate structure 150, thereby forming the gate extension 152. The RMG process is performed to deposit a high-k dielectric material followed by one or more work function material layers, thereby forming gate structure 150 with gate extension 152. The gate structure 150 includes high-k dielectric material and work function materials, as understood by one of ordinary skill in the art.

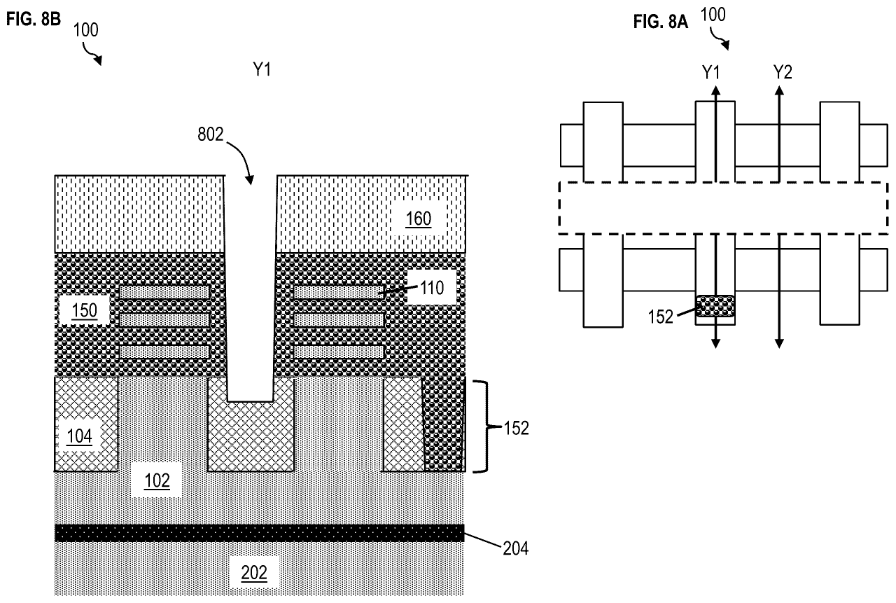

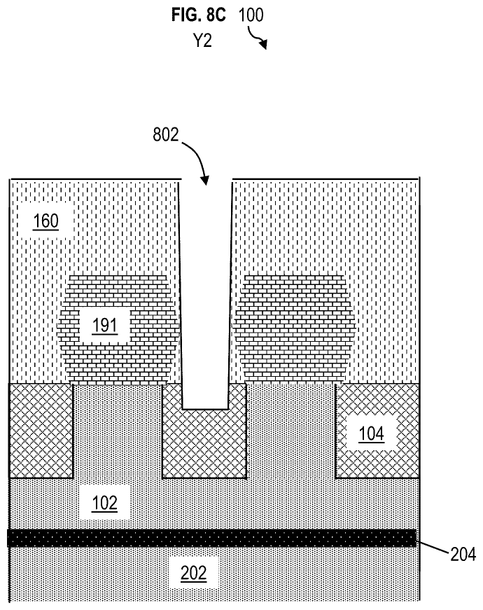

FIGS. 8A, 8B, and 8C depict the IC 100 after a gate cut. A block mask layer such as an organic patterning layer (OPL) can be formed and patterned. The patterned block mask layer is utilized to etch a cavity 802 in the gate structure 150 using, for example, a reactive ion etch (RIE). The block mask layer can be removed by ashing.

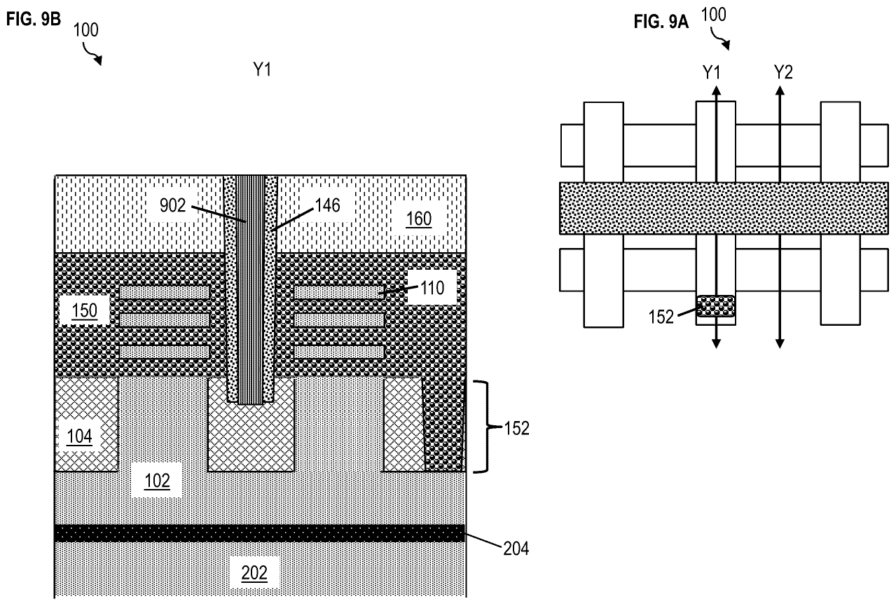

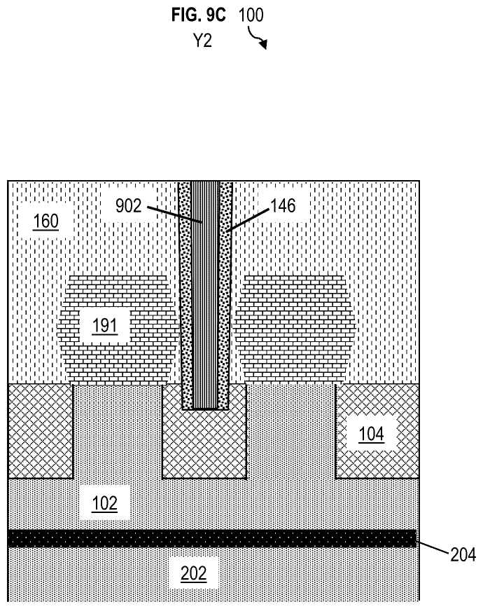

FIGS. 9A, 9B, and 9C depict the IC 100 after spacer deposition and inner dielectric fill. Spacer deposition is performed to form spacer material 146 in the cavity 802. Etch back of the spacer material 146 may be performed. The spacer material 146 lines the walls of the cavities 802. Example materials of the spacer material 146 can include nitride materials, such as SiN, SiBCN, SiOCN, SiOC, etc.

A RIE etch can be performed to open the bottom of the cavity 802. The RIE etch can be a post clean process. An inner dielectric fill material is performed to form inner dielectric fill 902. Chemical mechanical polishing/planarization (CMP) can be performed to planarize the top surface.

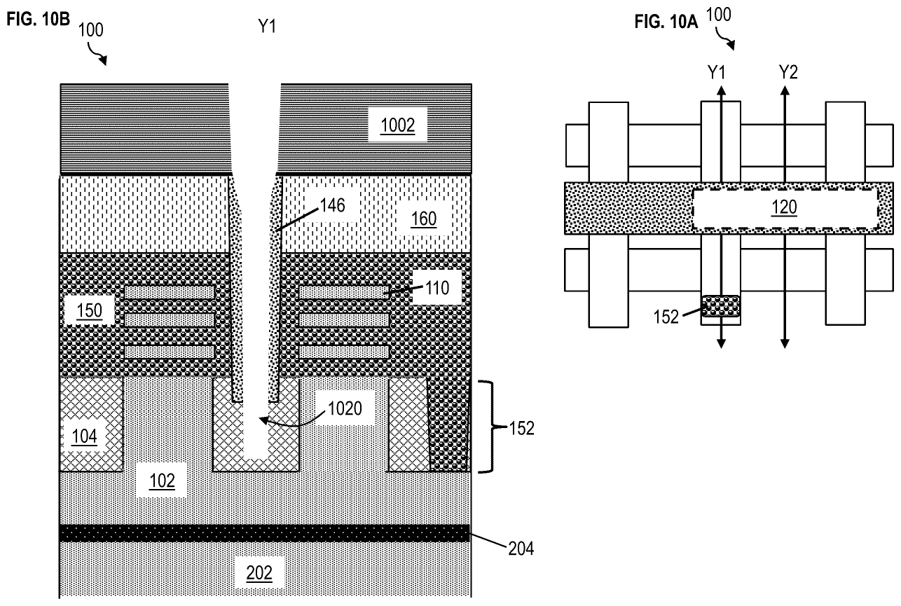

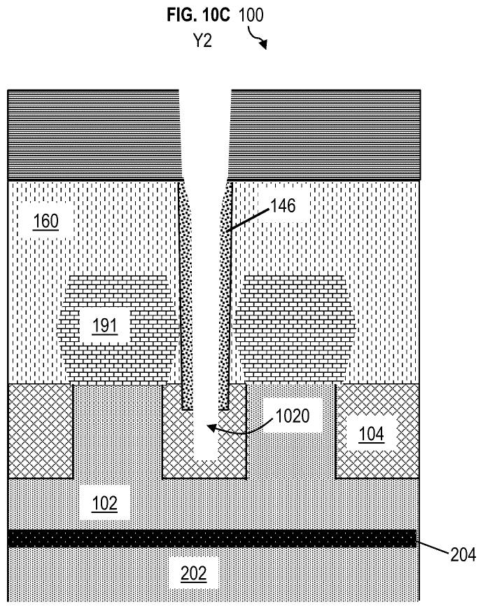

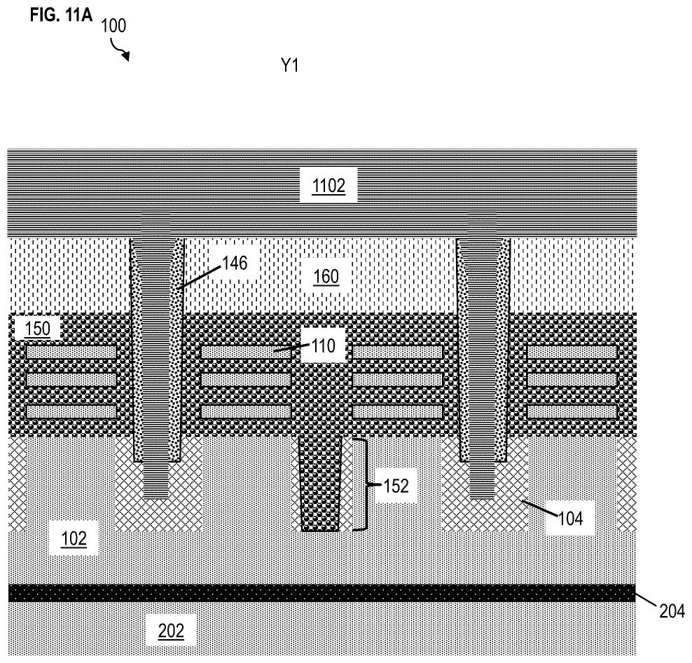

FIGS. 10A, 10B, and 10C depict the IC 100 after block mask patterning and via formation. A block mask layer 1002 is formed and patterned using lithography. Etching such as a RIE etch is performed to form open via 1020, which may be called an RV via, in the STI region 104. The etching is down to almost the bottom of the STI region 104 without breaking through. A post RIE clean may be performed.

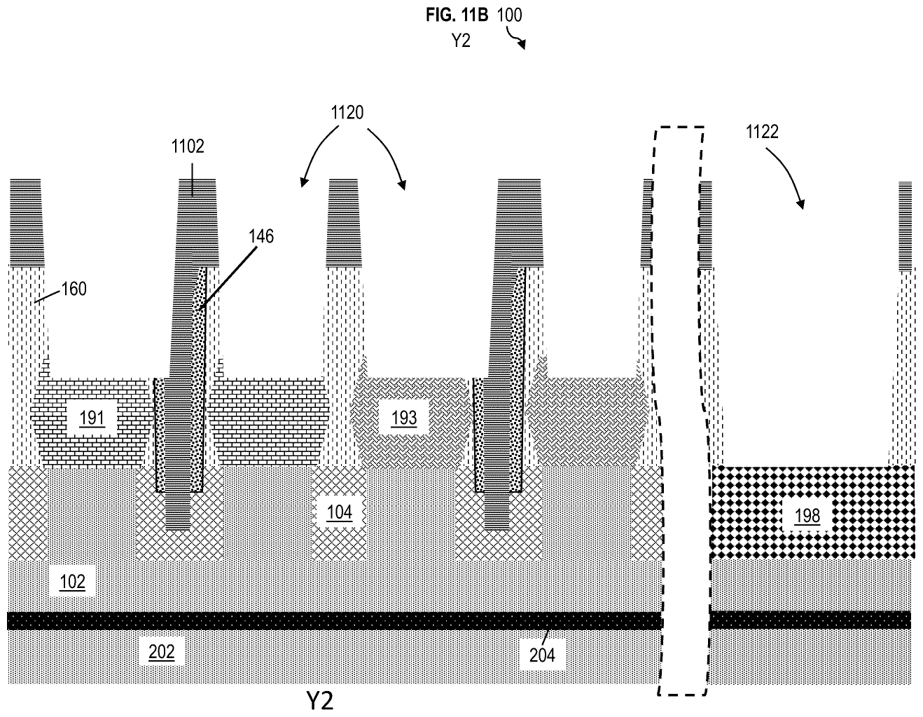

FIGS. 11A and 11B depict the IC 100 after block mask patterning and cavity formation for frontside source/drain contacts. The block mask layer 1002 is stripped by, for example, ashing.

A block mask layer 1102 is formed and patterned using lithography. Etching such as a RIE etch is performed to form cavities 1120 and 1122, which may be called frontside source/drain contact cavities. It is noted that the opening in the block mask layer 1102 used to pattern cavity 1122 is wider than the openings used to pattern cavities 1120, thereby resulting in a higher etch rate into the (ILD) frontside fill material 160 to expose the highly doped region 198.

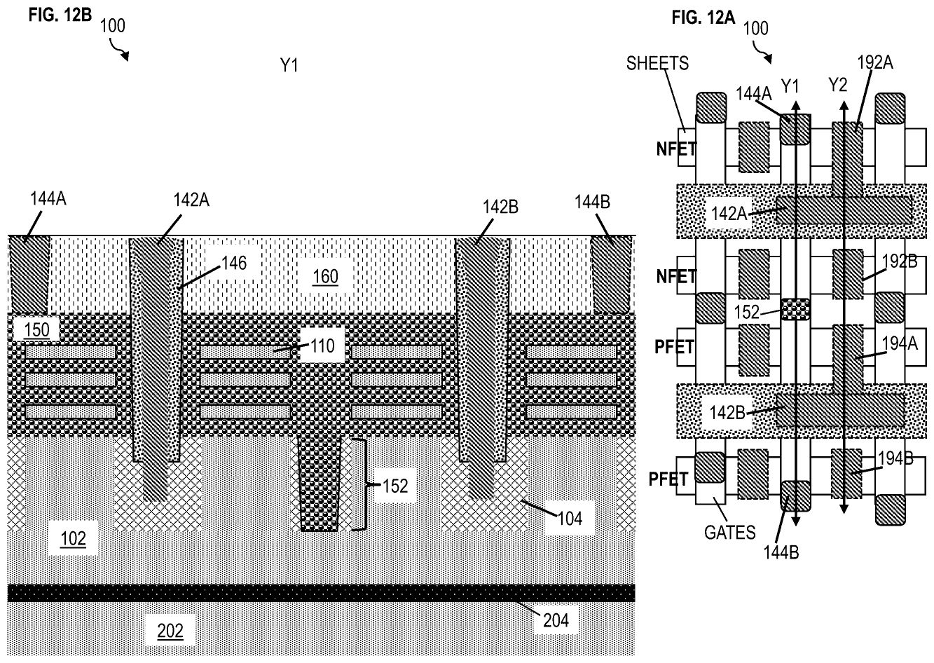

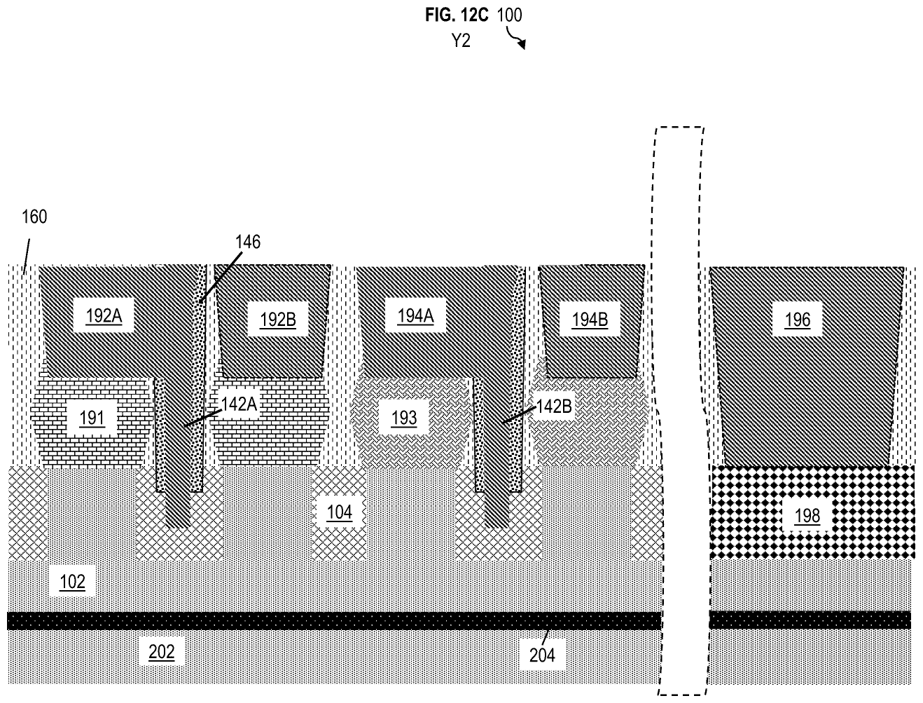

FIGS. 12A, 12B, and 12C depict the IC 100 after metallization for frontside gate contacts, frontside source/drain contacts, and source/drain vias. The block mask layer 1102 is stripped, for example, by ashing. Another block mask layer (not shown) is formed and patterned in preparation for etching cavities for gate contacts. The cavities for the gate contacts are etched, and the block mask is stripped. Metallization is performed to deposit metal, thereby forming frontside source/drain contacts 192A and 192B, frontside source/drain contacts 194A and 194B, source/drain vias 142A and 142B, and a (large) grounding contact 196. As can be seen, there are metal via extensions for the source, drain, and gate from the frontside to the backside.

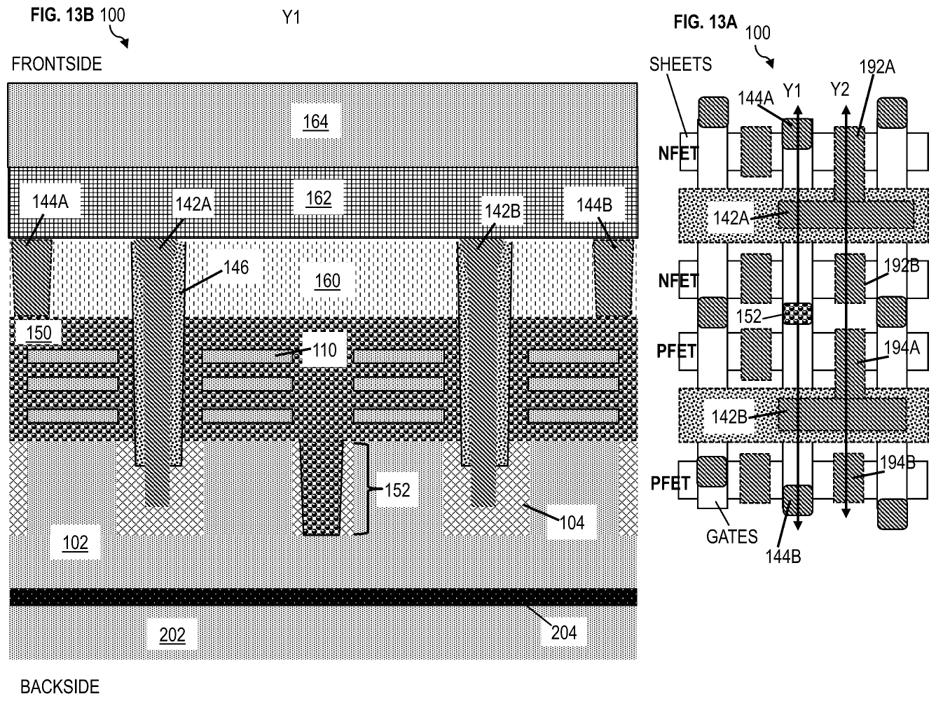

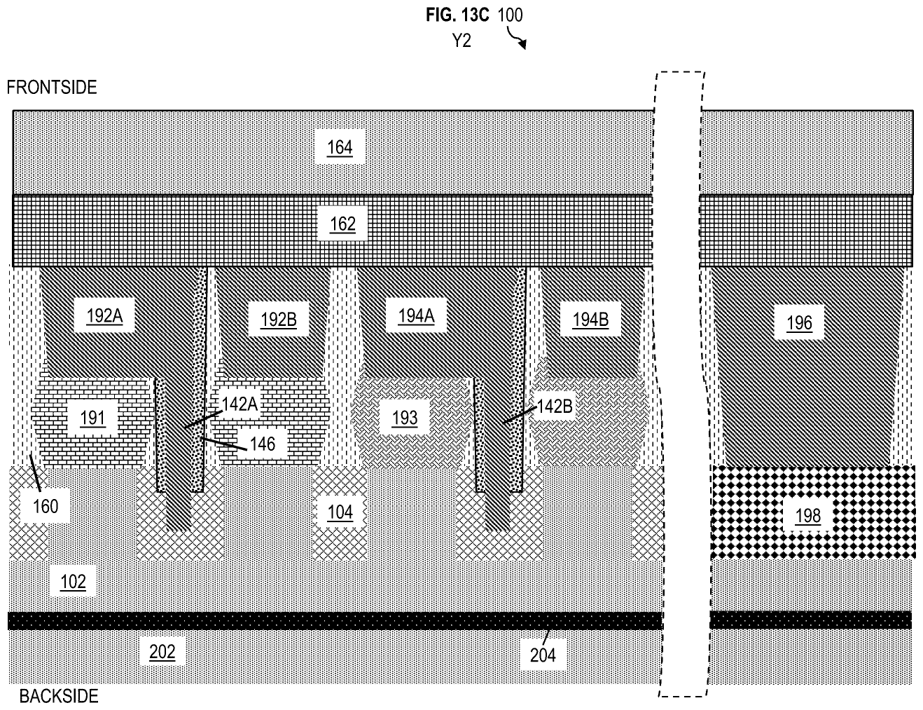

FIGS. 13A, 13B, and 13C depict the IC 100 after BEOL formation and carrier wafer bonding. BEOL processes are performed to form the frontside interconnect 162. A carrier wafer 164 is bonded to the frontside interconnect 162.

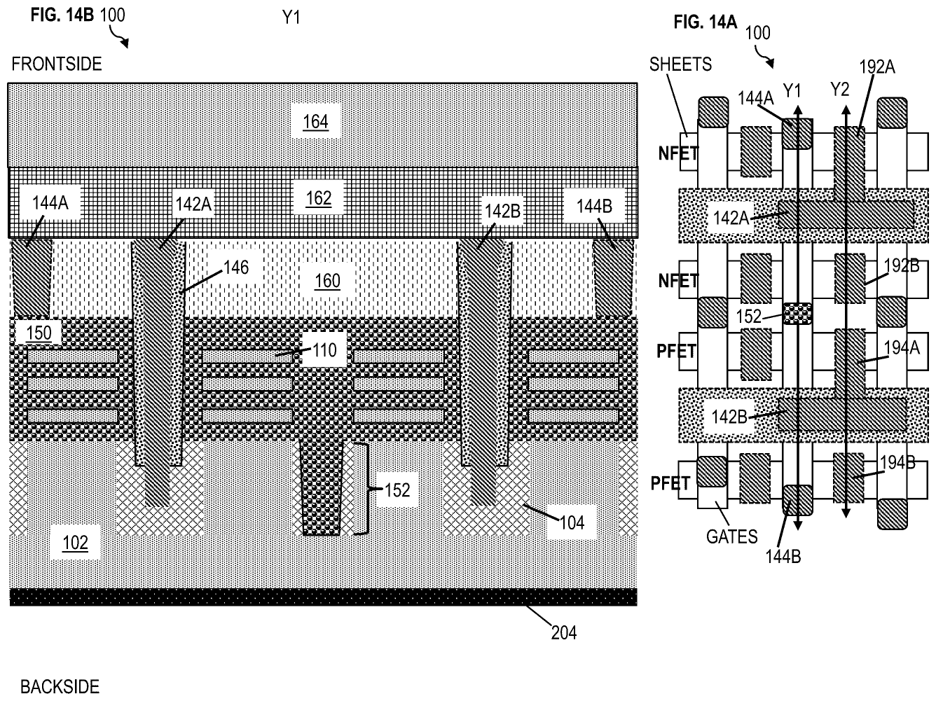

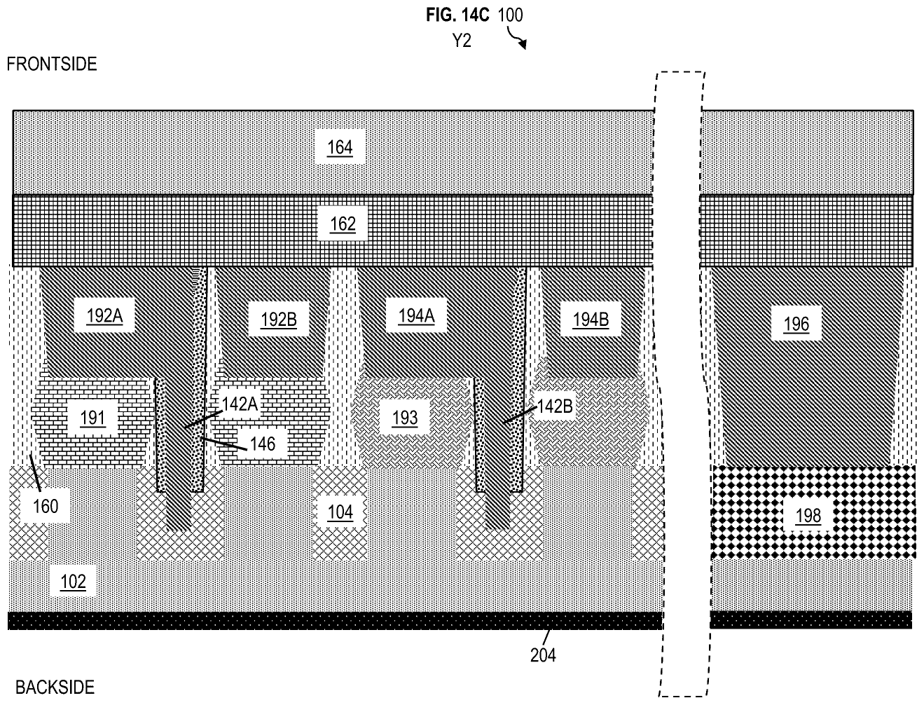

FIGS. 14A, 14B, and 14C depict the IC 100 after wafer flip and backside recess. It is noted that fabrication processes are being performed on the backside of the IC 100. For ease of understanding and to assist the reader, the top/bottom orientation of the wafer remains the same and is not flipped in the illustrations. Substrate grinding, CMP, and etching are performed to remove the lower substrate 202, where the removal of the lower substrate 202 stops on the etch stop layer which is the sacrificial layer 204. A wet etch may be performed.

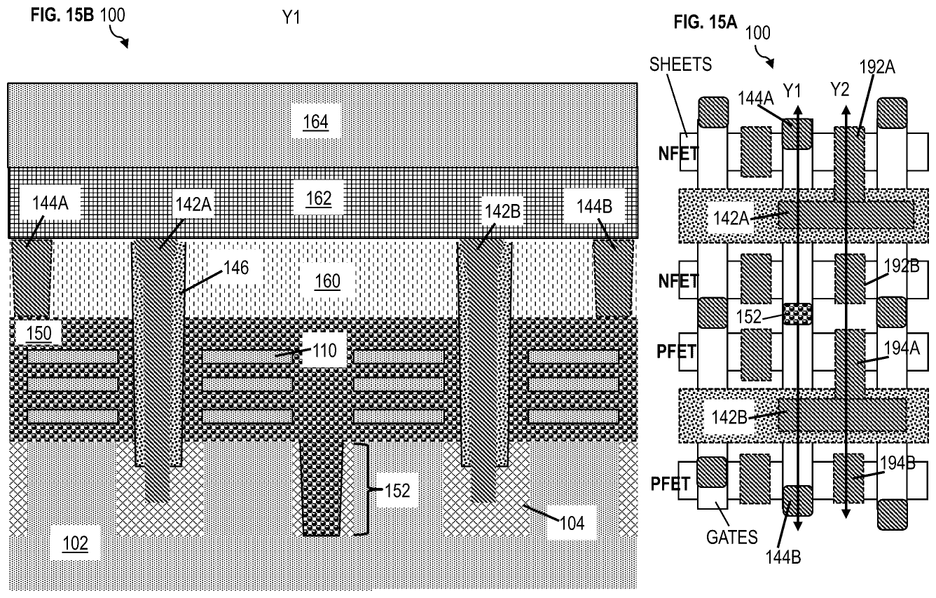

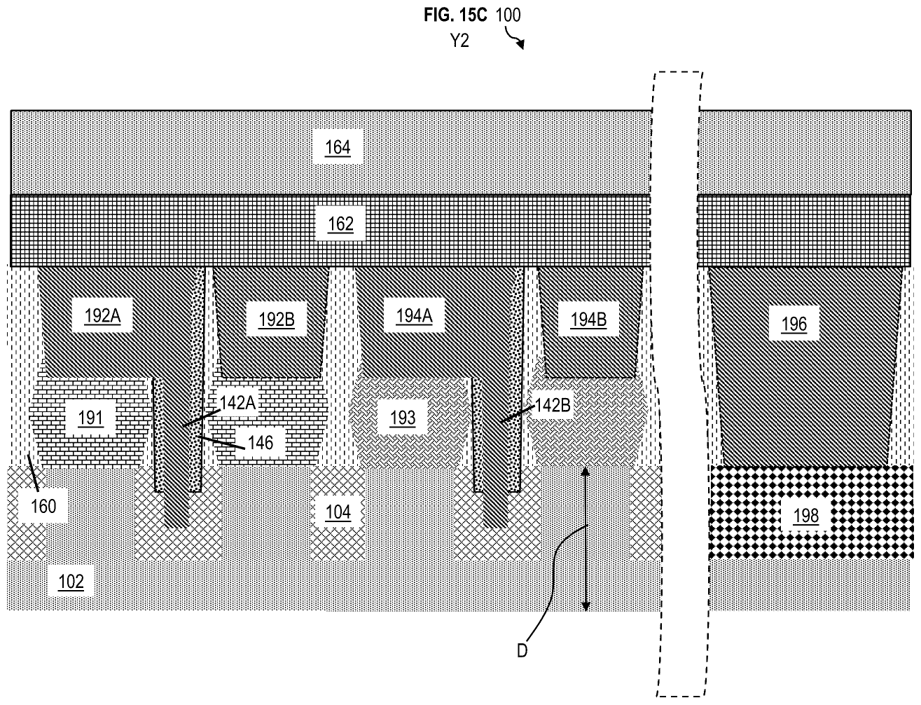

FIGS. 15A, 15B, and 15C depict the IC 100 after etch stop removal. Etching is performed to remove the sacrificial layer 204. The etching allows backside distance “D” of substrate material to remain of the substrate 102 for further processing. In one or more embodiments, the distance “D” is greater than the typical 30 nm. The distance D can be greater than 50 nm, greater than 60 nm, greater than 70 nm, greater than 80 nm, greater than 90 nm, greater than 100 nm, and so forth. The distance D can be about 150 nm or more.

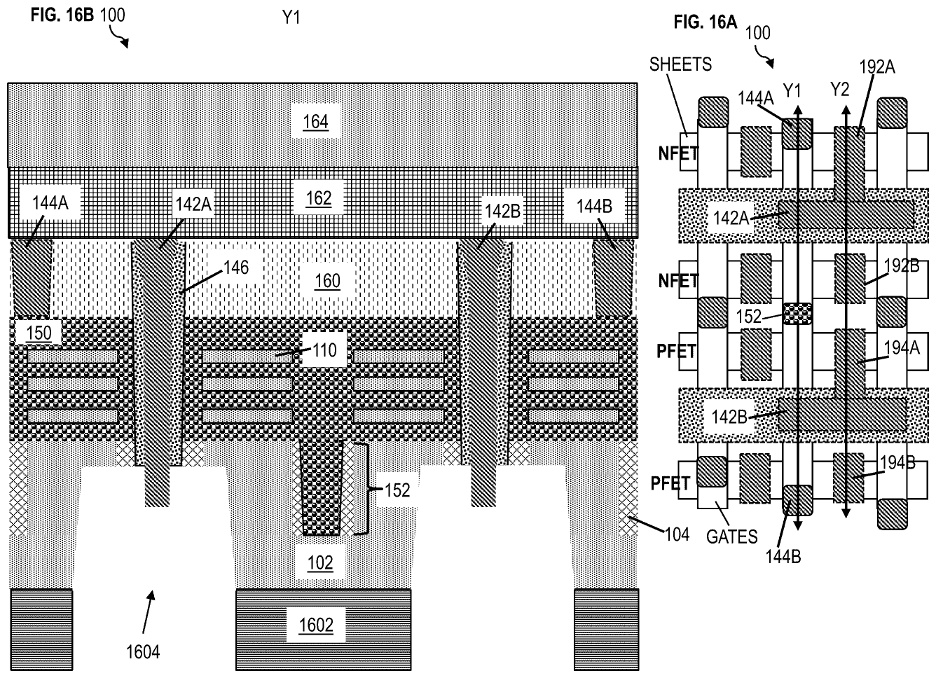

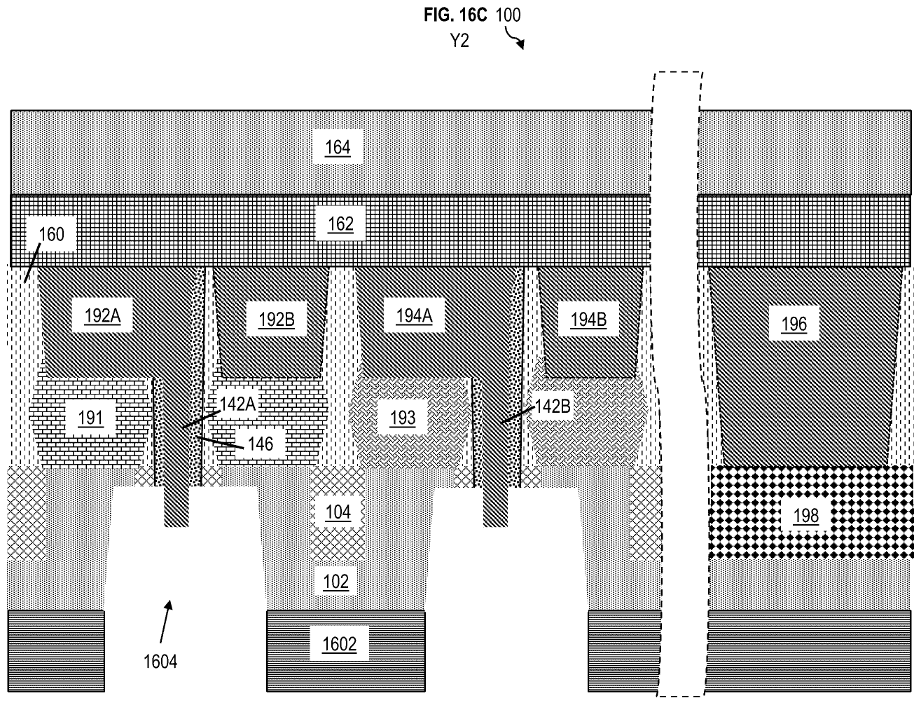

FIGS. 16A, 16B, and 16C depict the IC 100 after cavity formation for backside source/drain contacts. A block mask layer 1602 is formed and patterned using lithography. Etching such as a RIE etch is performed to form cavities 1604, which may be called backside source/drain contact cavities. The source/drain vias 142A and 142B are exposed in the cavities 1604.

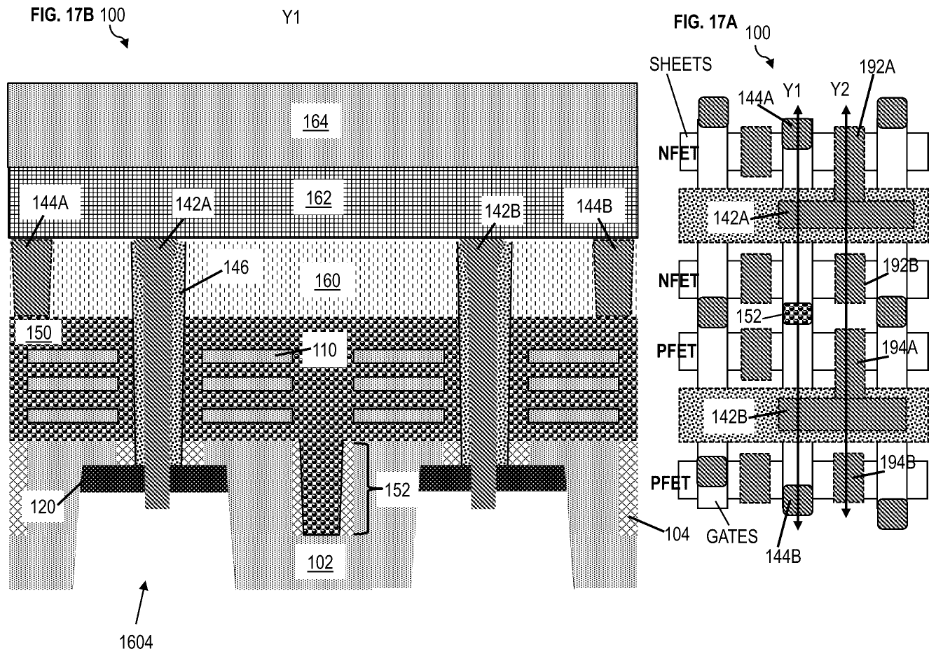

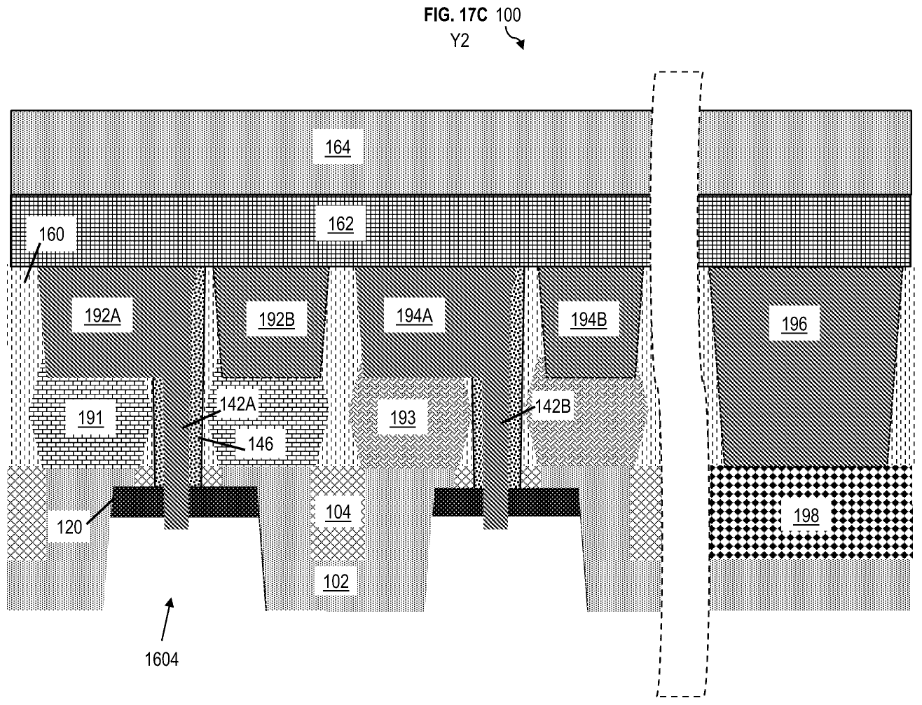

FIGS. 17A, 17B, and 17C depict the IC 100 after depositing interlayer dielectric material. The block mask layer 1602 is stripped, for example, by ashing. Backside fill material 120 is deposited and formed in the cavities 1604 adjacent to the sides of the source/drain vias 142A and 142B. Etch back can be performed to selectively etch the backside fill material, such that a portion of the source/drain vias 142A and 142B is exposed in the cavities 1604. The backside fill material 120 includes dielectric materials. The backside fill material 120 can include low-k and ultra-low-k dielectric materials.

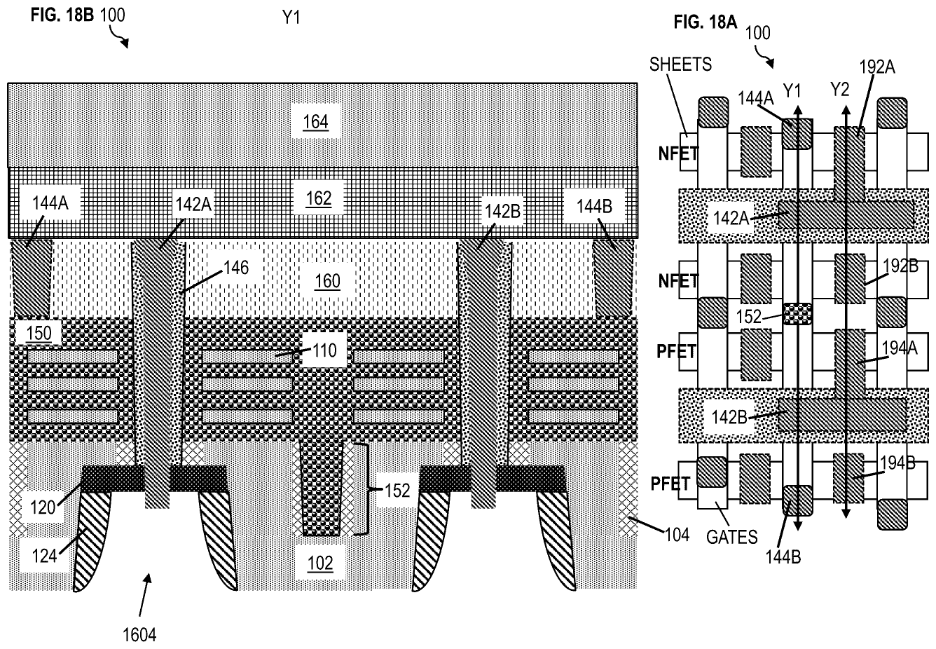

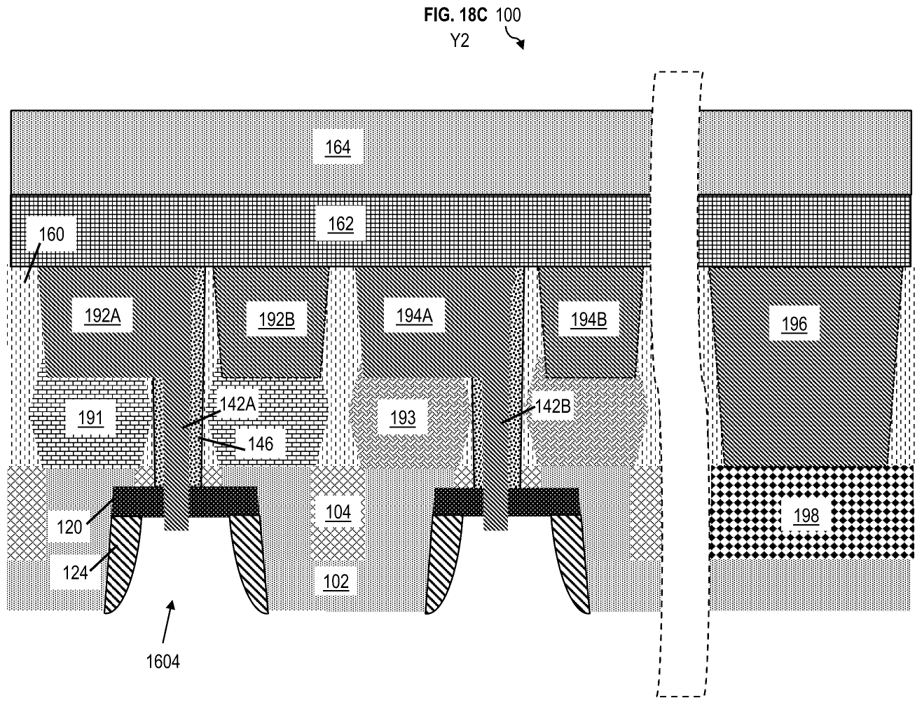

FIGS. 18A, 18B, and 18C depict the IC 100 after backside spacer formation. Spacer material 124 is formed on sides in the cavities 1604. The spacer material 124 is deposited and anisotropic etching is performed, in order to expose a portion of the source/drain vias 142A and 142B in the cavities 1604. The spacer material 124 can include dielectric materials. The spacer material 124 can include low-k and ultra-low-k dielectric materials. The spacer material 124 is a different material from the backside fill material 120 such that there is a different etch rate, in order to perform a selective etch.

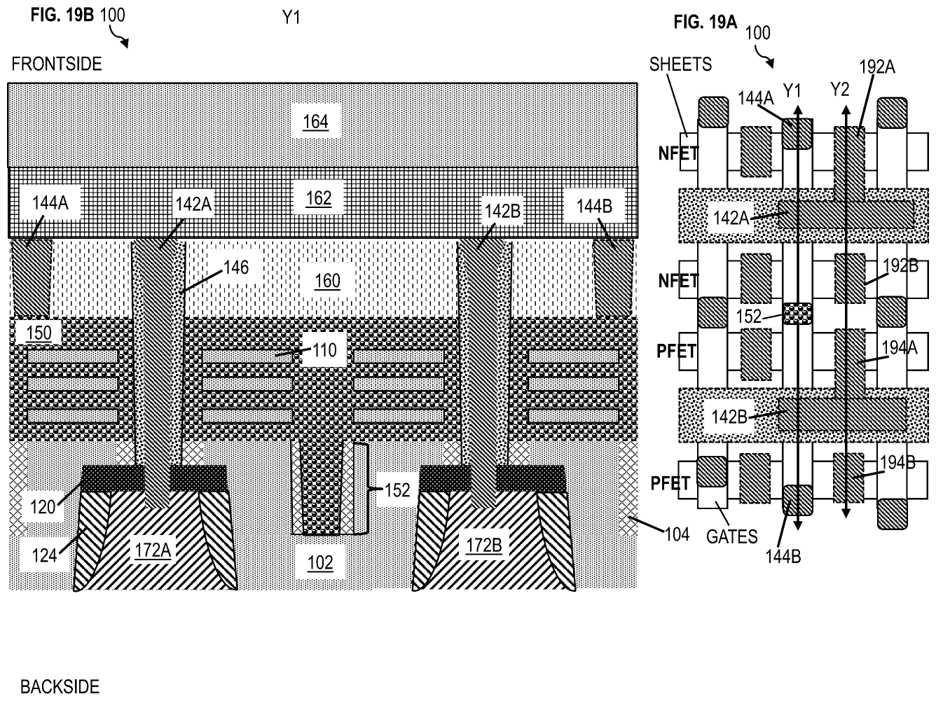

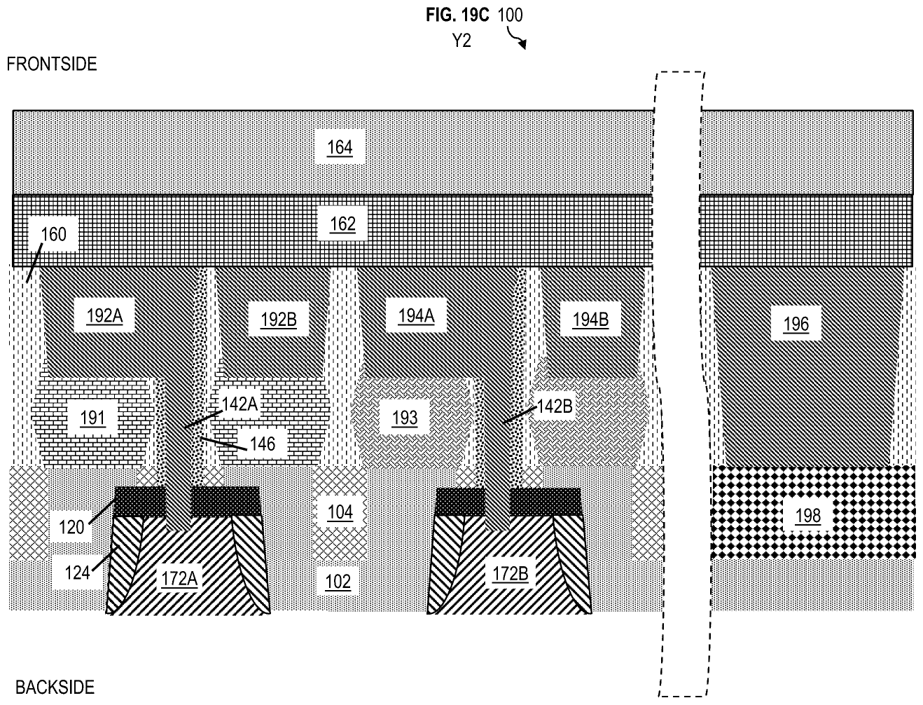

FIGS. 19A, 19B, and 19C depict the IC 100 after metallization. Metallization is performed to form backside source/drain contacts 172A and 172B. CMP is performed on the backside. As can be seen, the source/drain via 142A is connected to the frontside source/drain contact 192A on the frontside and connected to the backside source/drain contact 172A on the backside. Similarly, the source/drain via 142B is connected to the frontside source/drain contact 194A on the frontside and connected to the backside source/drain contact 172B on the backside.

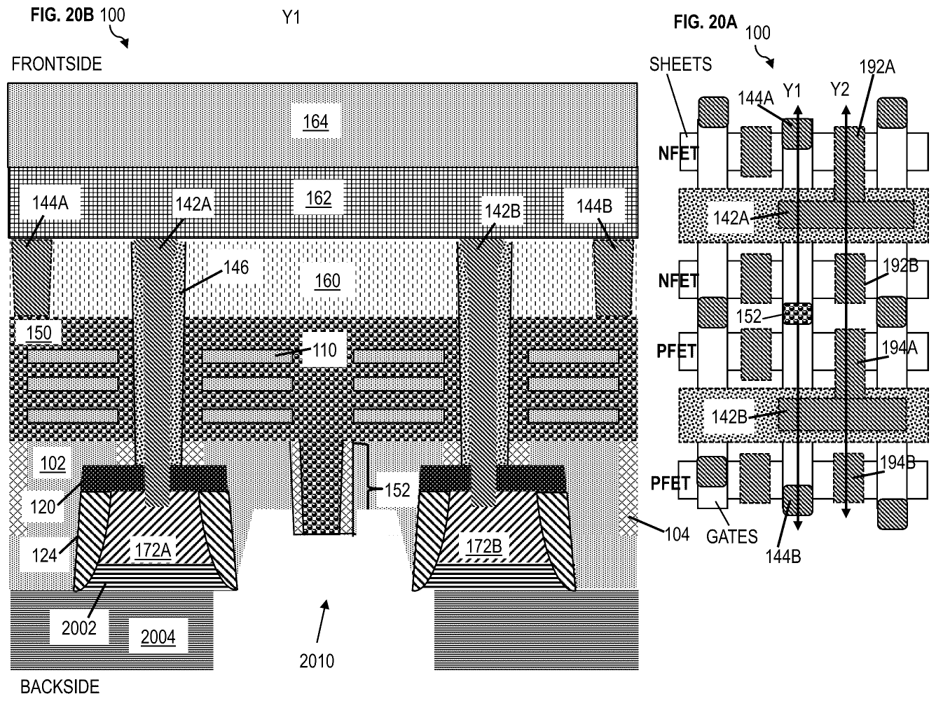

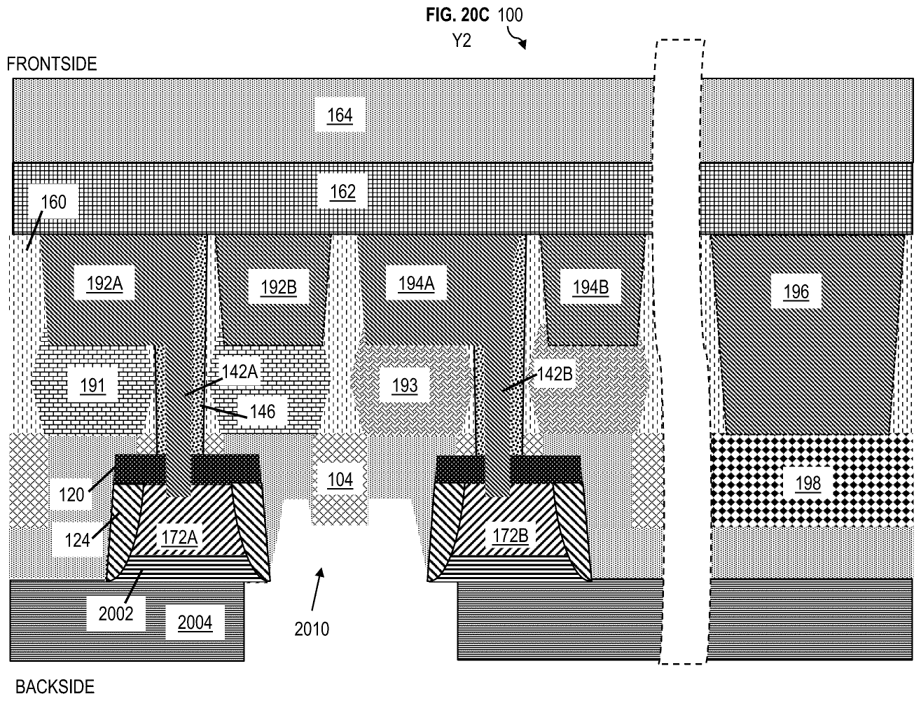

FIGS. 20A, 20B, and 20C depict the IC 100 after self-aligned clock signal patterning. The backside source/drain contacts 172A and 172B are recessed, and a dielectric cap 2002 is formed on the backside source/drain contacts 172A and 172B. CMP may be performed. A block mask layer 2004 is formed and patterned. Etching such as a RIE etch is performed to create trench 2010, which exposes a portion of the gate extension 152 of the gate structure 150 and the STI region 104.

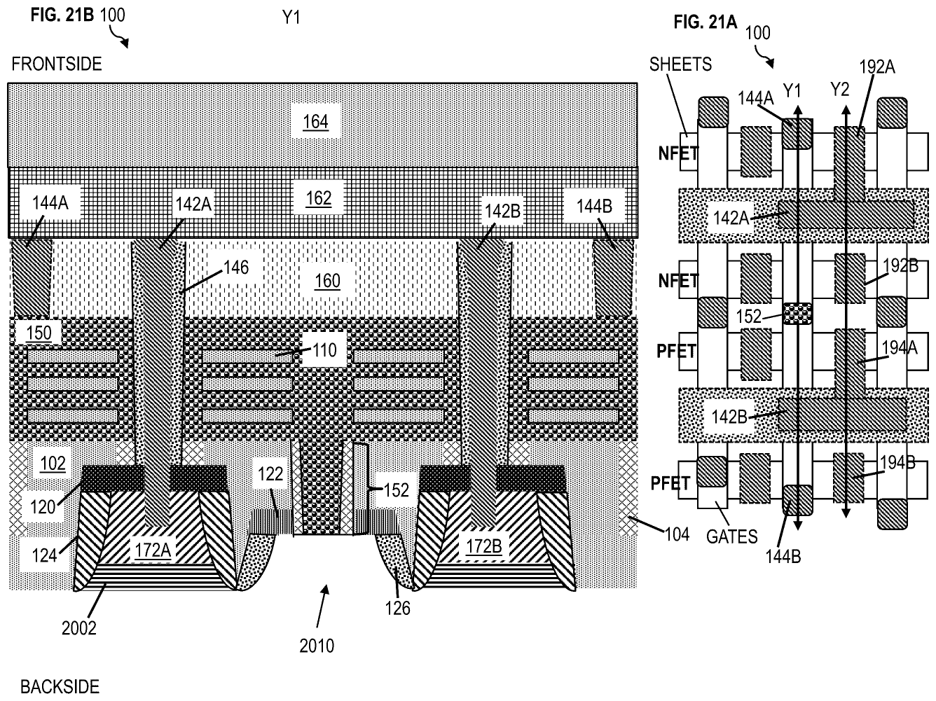

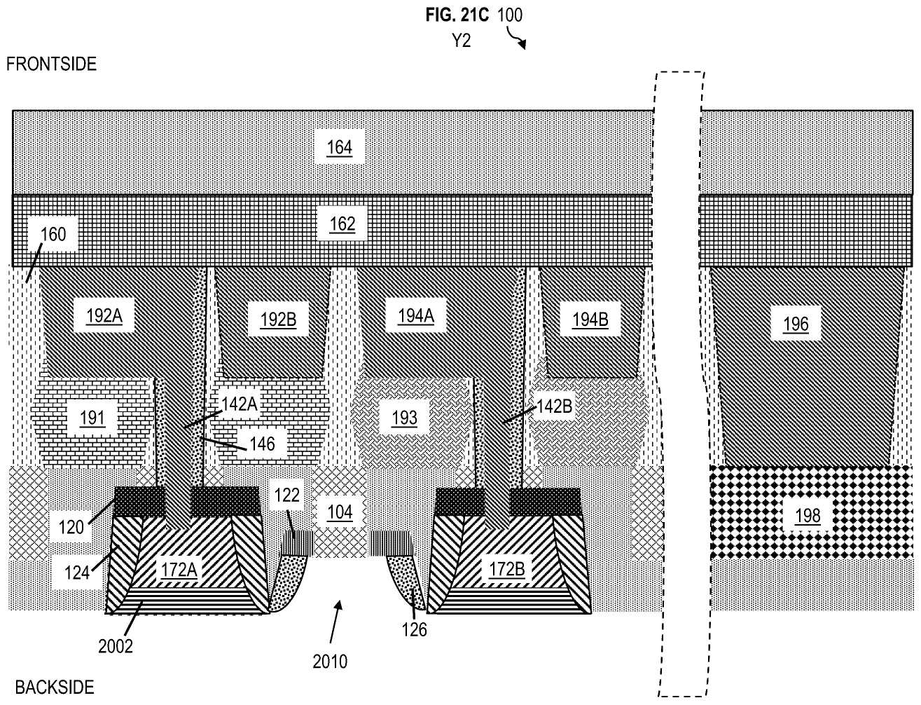

FIGS. 21A, 21B, and 21C depict the IC 100 after backside self-aligned clock signal top surface and sidewall dielectric spacer formation. An OPL ash can be performed to remove the block mask layer 2004.

While backside source/drain contacts 172A and 172B are protected by a dielectric cap 2002, the spacer material 122 is formed around portions of the STI region 104 and the gate extension 152. The spacer material is deposited and etch back is performed until portions of the STI region 104 and the gate extension 152 are exposed in the trench 2010. Further, spacer material 126 is deposited, and etched back is performed until the portions of the STI region 104 and the gate extension 152 are exposed in the trench 2010.

The spacer material 122 and spacer material 126 can include dielectric materials. The spacer material 122 and 126 can include low-k and ultra-low-k dielectric materials. However, the spacer material 126 is a different material from the spacer material 122 such that there is a different etch rate, in order to perform a selective etch.

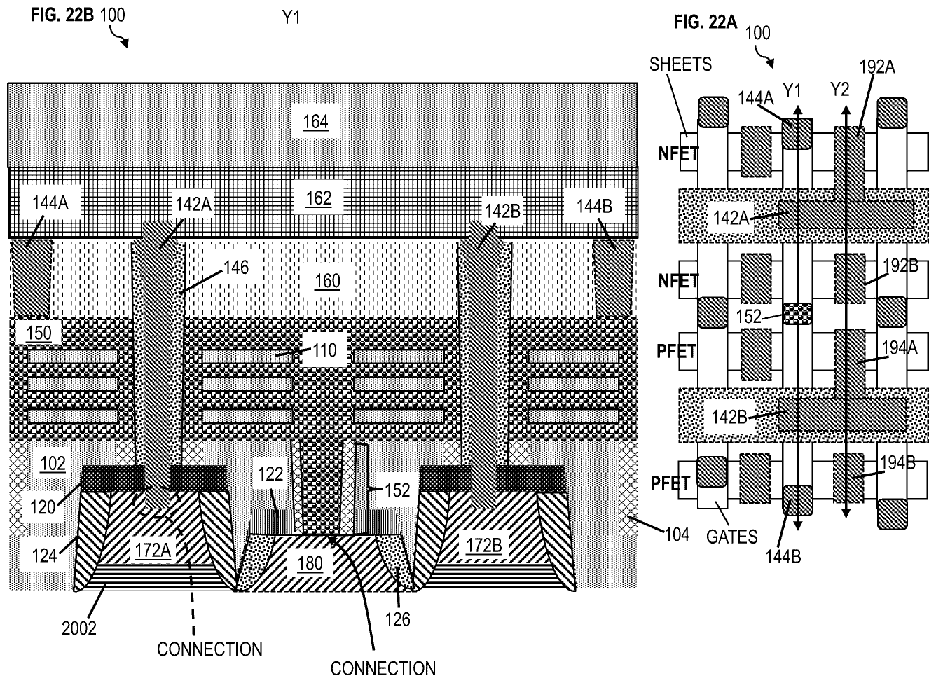

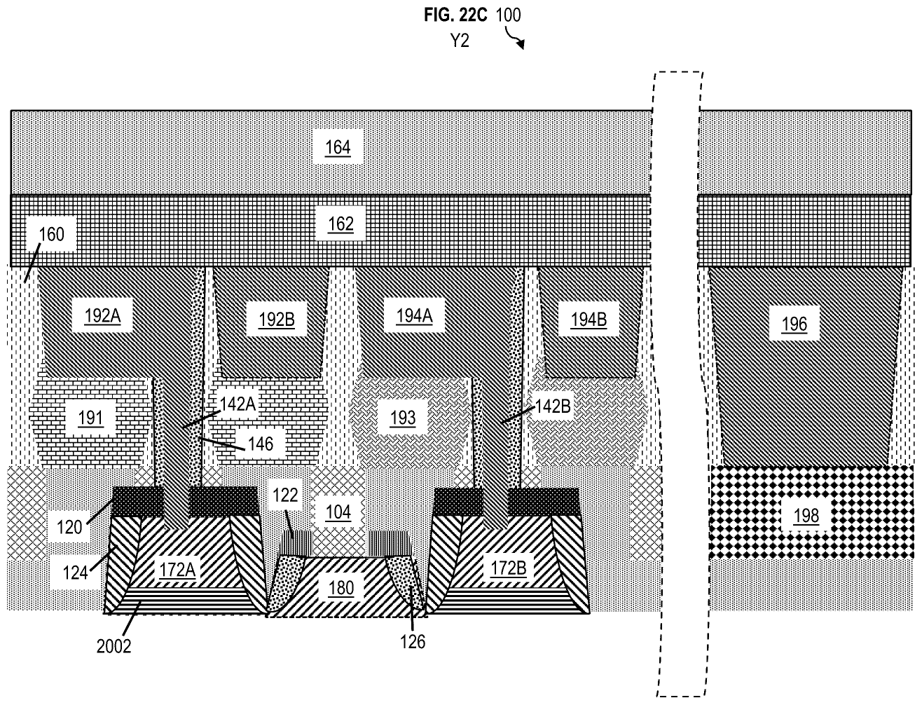

FIGS. 22A, 22B, and 22C depict the IC 100 after backside self-aligned clock signal metallization. Metallization is performed to form backside gate contact 180 as the self-aligned clock contact that connects to the backside interconnect 184 to receive the clock signal.

Referring back to FIGS. 1A, 1B, and 1C, the IC 100 is shown after dielectric cap removal, backside ILD fill, and backside via patterning, and backside power delivery network (BSPDN) formation. Etching is performed to remove the dielectric cap 2002. Backside fill material 186 is deposited and patterned with openings to expose portions of the backside source/drain contacts 172A and 172B and the backside gate contact 180. The openings are filled with metal to form the backside vias 174A and 174B and backside via 182. CMP may be performed, and the backside interconnect 184 is formed. The backside interconnect 184 can include a backside power distribution network.

A method of fabricating a semiconductor structure such as the IC 100 is discussed. Provided is a transistor (e.g., transistors 132, 134, 136, and 138) comprising epitaxial regions (e.g., epitaxial regions 191 and 193) and a gate structure 150 at a frontside, a gate extension 152 being connected at the frontside to the gate structure 150 and extending to a backside, the frontside being opposite the backside (e.g., as depicted in FIG. 1). Formed is a backside gate contact 180 connected at the backside to the gate extension 152. Formed is a source/drain via (e.g., source/drain vias 142A and 142B) coupled to one of the epitaxial regions (e.g., epitaxial regions 191 and 193), the source/drain via extending through the gate structure 150 from the frontside to the backside, the gate extension 152 extending further in the backside than the source/drain via (e.g., source/drain vias 142A and 142B).

In one or more embodiments, the gate extension 152 connects to a gate contact (e.g., backside gate contact 180) in the backside. The source/drain via (e.g., source/drain vias 142A and 142B) connects to a backside source/drain contact (e.g., backside source/drain contact 172A and 172B) in the backside.

Further, a connection of the gate extension 152 to a gate contact (e.g., backside gate contact 180) is at a different level in the backside than a connection of the source/drain via (e.g., source/drain vias 142A and 142B) to a backside source/drain contact (e.g., backside source/drain contact 172A and 172B). The gate contact (e.g., backside gate contact 180) is adjacent to the backside source/drain contact (e.g., backside source/drain contact 172A and 172B). The source/drain via (e.g., source/drain vias 142A and 142B) is coupled to a backside interconnect 184 by a backside source/drain contact (e.g., backside source/drain contact 172A and 172B), and the source/drain via replaces a portion of material (e.g., high-k dielectric material and/or gate metal) having formed the gate structure 150 and is surrounded by dielectric material (e.g., spacer material 146) so as to behave like a gate cut structure. The gate extension 152 is coupled to a backside interconnect 184 by a gate contact (e.g., backside gate contact 180). The gate extension 152 comprises material of the gate structure 150. Dielectric material surrounds sides of the gate extension 152 so as to separate the gate extension 152 from the substrate 102. The gate extension 152 is positioned between the transistor (e.g., transistors 132 and 134) and a complimentary transistor (e.g., transistors 136 and 138).

During metallization, example metals utilized to form the contacts may include aluminum (Al), platinum (Pt), gold (Au), tungsten (W), titanium (Ti), copper, etc., or any combination thereof. Various metal allows may be utilized as conductive materials. It should be appreciated that a silicide may be formed between the contact metal and the semiconductor material of the source/drains.

The gate material or gate structures include high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Interlayer dielectric (ILD) material or fill material can be a low-k dielectric material, an ultra-low-k dielectric material, etc. The ILD material can include SiO₂, or low-k and ultra-low-k dielectric materials with a k-value <4. In one or more embodiments, the ILD material or fill material can be SiO₂, SiN, a low-k dielectric material or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a transistor comprising epitaxial regions and a gate structure at a frontside, a gate extension being connected at the frontside to the gate structure and extending to a backside, the frontside being opposite the backside;
a backside gate contact connected at the backside to the gate extension; and
a source/drain via coupled to one of the epitaxial regions, the source/drain via extending through the gate structure from the frontside to the backside, the gate extension extending further in the backside than the source/drain via.

2. The semiconductor structure of claim 1, wherein the gate extension connects to a gate contact in the backside.

3. The semiconductor structure of claim 1, wherein the source/drain via connects to a backside source/drain contact in the backside.

4. The semiconductor structure of claim 1, wherein a first connection of the gate extension to a gate contact is at a different level in the backside than a second connection of the source/drain via to a backside source/drain contact.

5. The semiconductor structure of claim 4, wherein the gate contact is adjacent to the backside source/drain contact.

6. The semiconductor structure of claim 1, wherein:
the source/drain via is coupled to a backside interconnect by a backside source/drain contact; and
the source/drain via replaces a portion of material having formed the gate structure and is surrounded by dielectric material.

7. The semiconductor structure of claim 1, wherein the gate extension is coupled to a backside interconnect by a gate contact.

8. The semiconductor structure of claim 1, wherein the gate extension comprises material of the gate structure.

9. The semiconductor structure of claim 1, wherein dielectric material surrounds sides of the gate extension so as to separate the gate extension from a substrate.

10. The semiconductor structure of claim 1, wherein the gate extension is positioned between the transistor and a complimentary transistor.

11. A method comprising:
providing a transistor comprising epitaxial regions and a gate structure at a frontside, a gate extension being connected at the frontside to the gate structure and extending to a backside, the frontside being opposite the backside, wherein a backside gate contact is connected at the backside to the gate extension; and
forming a source/drain via coupled to one of the epitaxial regions, the source/drain via extending through the gate structure from the frontside to the backside, the gate extension extending further in the backside than the source/drain via.

12. The method of claim 11, wherein the gate extension connects to a gate contact in the backside.

13. The method of claim 11, wherein the source/drain via connects to a backside source/drain contact in the backside.

14. The method of claim 11, wherein a first connection of the gate extension to a gate contact is at a different level in the backside than a second connection of the source/drain via to a backside source/drain contact.

15. The method of claim 14, wherein the gate contact is adjacent to the backside source/drain contact.

16. The method of claim 11, wherein:
the source/drain via is coupled to a backside interconnect by a backside source/drain contact; and
the source/drain via replaces a portion of material having formed the gate structure and is surrounded by dielectric material.

17. The method of claim 11, wherein the gate extension is coupled to a backside interconnect by a gate contact.

18. The method of claim 11, wherein the gate extension comprises material of the gate structure.

19. The method of claim 11, wherein:
dielectric material surrounds sides of the gate extension so as to separate the gate extension from a substrate; and
the gate extension is positioned between the transistor and a complimentary transistor.

20. A semiconductor structure comprising:
a first transistor comprising epitaxial regions and a gate structure at a frontside, a gate extension being connected at the frontside to the gate structure and extending to a backside, the frontside being opposite the backside;
a second transistor comprising the gate structure, wherein the gate extension is positioned between the first and second transistors, the first and second transistors being complimentary transistors;
a backside gate contact connected at the backside to the gate extension; and
a source/drain via coupled to one of the epitaxial regions, the source/drain via extending through the gate structure from the frontside to the backside, the gate extension extending further in the backside than the source/drain via.
